(19) United States
(12) Patent Application Publication
(10) Pub. No.: US 2026/0206244 A1
(43) Pub. Date: Jul. 16, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Yi-Chen LO, Zhubei City (TW); Pinyen LIN, Zhubei City, Hsinchu County (TW)

(73) Assignee: Taiwan Semiconductor Manufacturing Company, Ltd., Hsinchu (TW)

(21) Appl. No.: 19/016,379

(22) Filed: Jan. 10, 2025

(51) Int. Cl. H10D 30/01; H10D 30/00

(52) U.S. Cl. CPC H10D 30/0198; H10D 30/0191; H10D 30/501

(57) ABSTRACT

A method for manufacturing a semiconductor structure includes forming an etch stop layer over a substrate, and forming a stack over the etch stop layer. The stack includes first and second semiconductor layers alternating stacked. The method further includes recessing the stack and the etch stop layer to form a fin, forming a dummy gate structure over the fin, forming source/drain trenches on opposite sides of the dummy gate structure, forming epitaxial layers in the source/drain trenches, forming source/drain features over the epitaxial layers, replacing the dummy gate structure and the first semiconductor layers with a gate structure, removing the substrate, forming a first dielectric layer under the etch stop layer and the epitaxial layers, and replacing a portion of the first dielectric layer and one of the epitaxial layers with a via under and electrically connected to one of the source/drain features.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIGS. 5, 6, 7, and 8 are perspective views of a workpiece at various fabrication stages, in accordance with some embodiments of the present disclosure.

FIGS. 9A, 10A, 11A, 12A, 13A, 14A, 15A, 16A, 17A, 18A, 19A, 20A, 21A, 22A, 23A, 24A, 25A, 26A, 27A, and 28A are X-Z cross-sectional views of the workpiece at various fabrication stages along a line A-A′ of FIG. 8, in accordance with some embodiments of the present disclosure.

FIGS. 9B, 10B, 11B, 12B, 13B, 14B, 15B, 16B, 17B, 18B, 19B, 20B, 21B, 22B, 23B, 24B, 25B, 26B, 27B, and 28B are Y-Z cross-sectional views of the workpiece at various fabrication stages along a line B-B′ of FIG. 8, in accordance with some embodiments of the present disclosure.

FIGS. 29A and 29B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

FIGS. 30A and 30B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

FIGS. 31A and 31B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

FIGS. 32A and 32B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

FIGS. 33A and 33B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

FIGS. 34A and 34B are respectively an X-Z cross-sectional view and a Y-Z cross-sectional view of the workpiece at a fabrication stage along the lines A-A′ and B-B′ of FIG. 8, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including GAA structures with an etch stop layer under the gate structure, such that the gate structure is protected during the removal of the substrate for the backside interconnection structure. The details of the structure and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

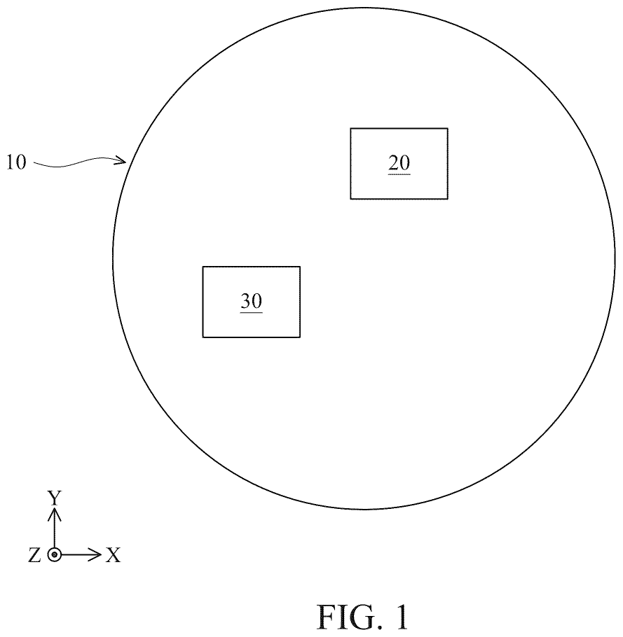

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

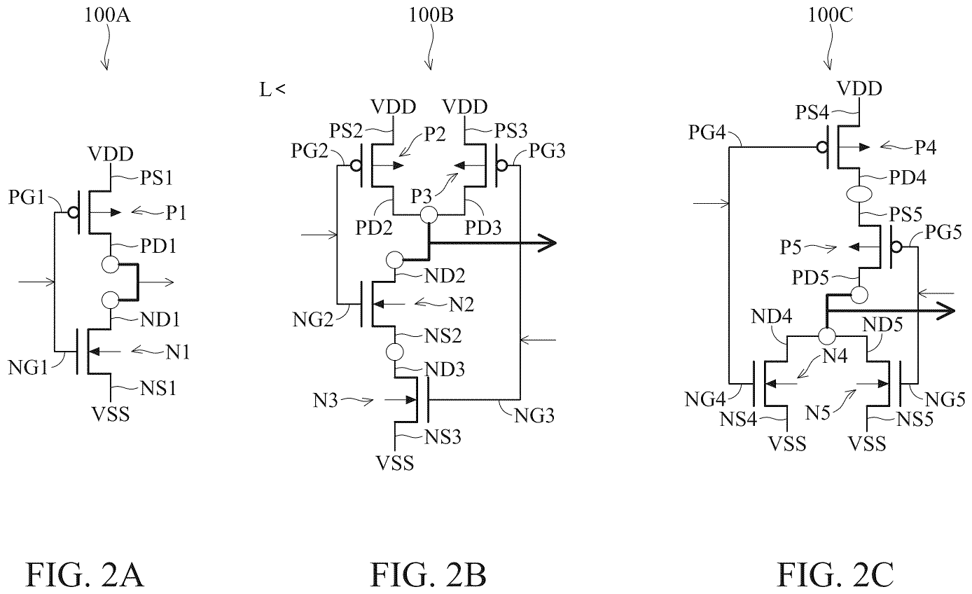

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

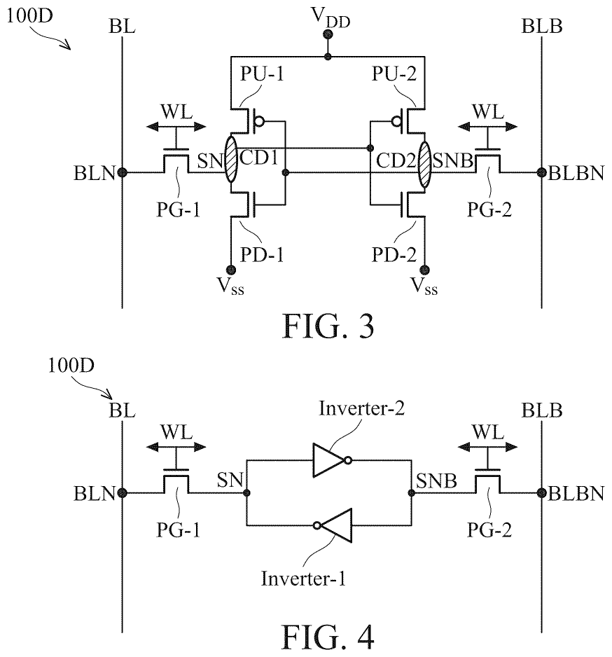

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inveter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Invereter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) VDD, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) Vss, and the first common drain.

A gate of pull-up transistor PU-2 interposes a source, which is electrically coupled to the first power supply voltage via voltage node VDD, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node Vss, and the second common drain.

The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary GAA transistors for the circuit cells and the SRAM cells discussed above are illustrated and described below. More specifically, the manufacturing method and the structure of GAA transistors with improved dielectric layer between nanostructures and substrate for the circuit cells and the SRAM cells discussed above are illustrated and described below. However, it should be understood that the application should not be limited to a particular type of device, except as specifically claimed.

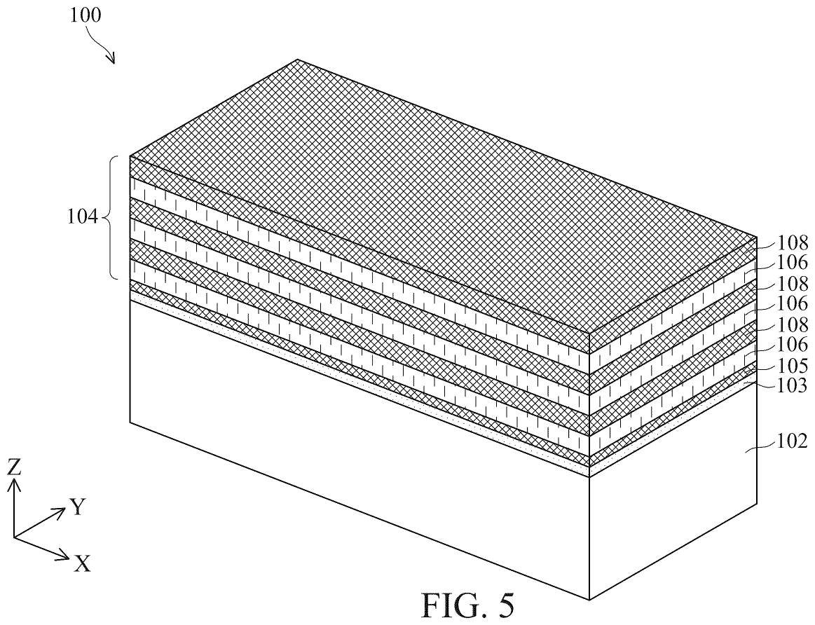

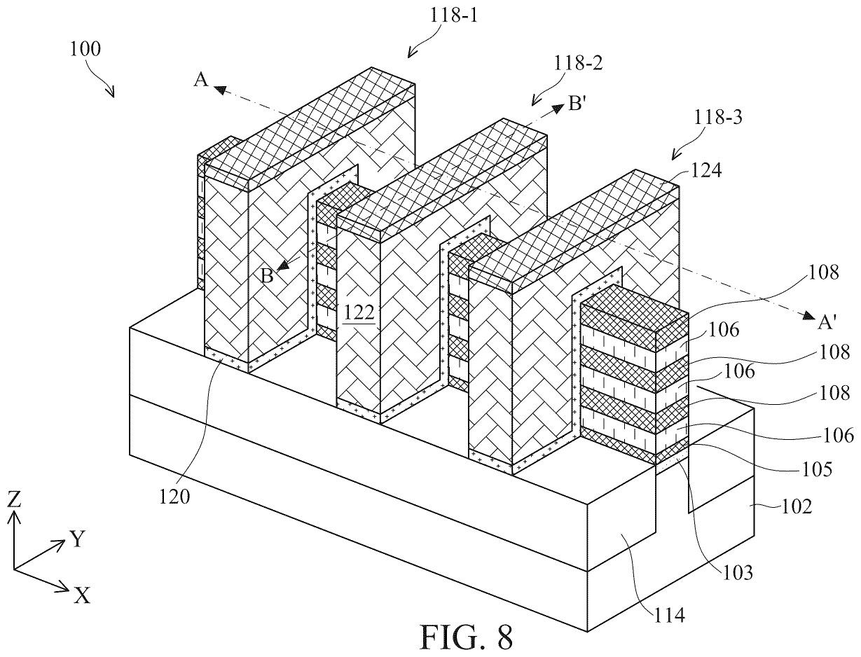

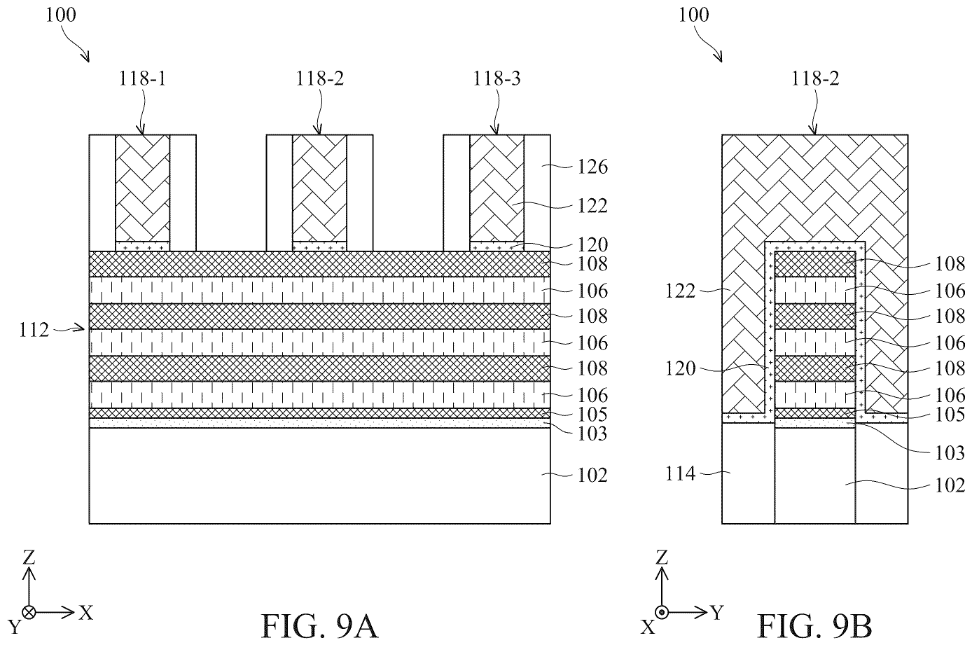

FIGS. 5, 6, 7, and 8 are perspective views of a workpiece 100 at various fabrication stages, in accordance with some embodiments of the present disclosure. FIGS. 9A, 10A, 11A, 12A, 13A, 14A, 15A, 16A, 17A, 18A, 19A, 20A, 21A, 22A, 23A, 24A, 25A, 26A, 27A, and 28A are X-Z cross-sectional views of the workpiece 100 at various fabrication stages along a line A-A′ of FIG. 8, in accordance with some embodiments of the present disclosure. FIGS. 9B, 10B, 11B, 12B, 13B, 14B, 15B, 16B, 17B, 18B, 19B, 20B, 21B, 22B, 23B, 24B, 25B, 26B, 27B, and 28B are Y-Z cross-sectional views of the workpiece 100 at various fabrication stages along a line B-B′ of FIG. 8, in accordance with some embodiments of the present disclosure.

Referring to FIG. 5, the workpiece 100 is provided. The workpiece 100 may include a substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GalnP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates. Because the workpiece 100 will be fabricated into a semiconductor structure upon conclusion of the fabrication processes, the workpiece 100 may be referred to as the semiconductor structure 100 as the context requires.

Still referring to FIG. 5, an etch stop layer 103 is formed over the substrate 102. The etch stop layer 103 is single crystal for growing sequent semiconductor layers (e.g., semiconductor layers 106 and 108) over the etch stop layer 103. Therefore, the etch stop layer 103 may also be referred to as the single crystal layer. In some embodiments, the etch stop layer 103 may include dielectric material (and may also be referred to as the dielectric layer). The etch stop layer 103 may include SiGeC, SiC, or a combination thereof, or the like. In some embodiments, a thickness of the etch stop layer is in a range from about 1 nm to about 3 nm.

Still referring to FIG. 5, after the formation of the etch stop layer 103, a semiconductor layer 105 is formed over the etch stop layer 103. More specifically, the semiconductor layer 105 is epitaxially grown over (on) the etch stop layer 103 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. As discussed above, the etch stop layer 103 is single crystal, such that the semiconductor layer 105 is also single crystal. In some embodiments, the semiconductor layer 105 is formed of silicon (Si) and may also be referred to as the silicon layer. In some embodiments, a thickness of the semiconductor layer 105 is greater than 1 nm.

Still referring to FIG. 5, after the formation of the semiconductor layer 105, a stack 104 is formed over the semiconductor layer 105, the etch stop layer 103, and the substrate 102. The stack 104 includes semiconductor layers 106 and 108 over the semiconductor layer 105, and the semiconductor layers 106 and 108 are alternatingly stacked in the Z-direction. The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). The semiconductor layers 108 and the semiconductor layer 105 have the same material and composition (e.g. silicon (Si)). In these embodiments, the additional germanium content in the semiconductor layers 106 allow selective removal or recess of the semiconductor layers 106 without substantial damages to the semiconductor layers 105 and 108, so that the semiconductor layers 106 are also referred to as sacrificial layers.

In some embodiments, the semiconductor layers 106 and 108 are epitaxially grown over (on) the semiconductor layer 105 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104.

It should be noted that three (3) layers of the semiconductor layers 106 and three (3) layers of the semiconductor layers 108 are alternately and vertically arranged (or stacked) as shown in FIG. 5, which are for illustrative purposes only and not intended to be limiting beyond what is specifically recited in the claims. The number of layers depends on the desired number of channels members for the semiconductor device. In some embodiments, there may be from 2 to 10 semiconductor layers 106 alternating with 2 to 10 semiconductor layers 108 in the stack 104.

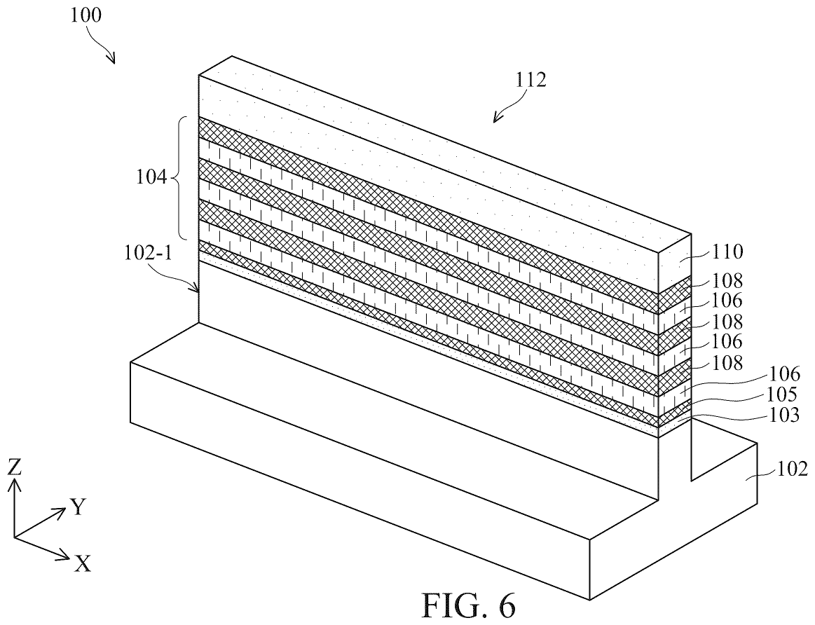

Referring to FIG. 6, the substrate 102, the etch stop layer 103, the semiconductor layer 105, and the stack 104 are then patterned and recessed to form a fin 112 over the substrate 102. For patterning purposes, the workpiece 100 may also include a hard mask layer 110 over the stack 104 before the patterning of the substrate 102, the etch stop layer 103, the semiconductor layer 105, and the stack 104. The hard mask layer 110 may be a single layer or a multi-layer. In some embodiments, the hard mask layer 110 is a single layer and includes a silicon germanium layer. In some embodiments, the hard mask layer 110 is a multi-layer and includes a silicon nitride layer and a silicon oxide layer over the silicon nitride layer. In some other embodiments, the hard mask layer 110 is a multi-layer and includes a silicon germanium layer and a silicon layer over the silicon germanium layer.

As shown in FIG. 6, the fin 112 includes a base fin 102-1 formed from a portion of the substrate 102 and a stack portion formed from the etch stop layer 103, the semiconductor layer 105, and the stack 104 over the base portion. In some aspects, the base fin 102-1 protrudes from the substrate 102. The fin 112 may include the etch stop layer 103, the semiconductor layer 105, and the semiconductor layers 106 and 108 alternating stacked in the Z-direction. The fin 112 extends lengthwise (e.g., longitudinally) in the X-direction, as shown in FIG. 6. Although one fin 112 is formed and shown herein, more fins may be formed, such as two or more fins.

The fins 112 may be patterned using suitable processes including double-patterning or multi-patterning processes. For example, in some embodiments, a material layer of the hard mask layer 110 is formed over the substrate 102 and patterned into the hard mask layer 110 using a photolithography process. One or more etching processes are then performed to etch the etch stop layer 103, the semiconductor layer 105, and the stack 104 and top portions of the substrate 102 not covered by the hard mask layer 110 to form the fin 112. The etching process may include dry etching, wet etching, reactive ion etching (RIE), and/or other suitable processes.

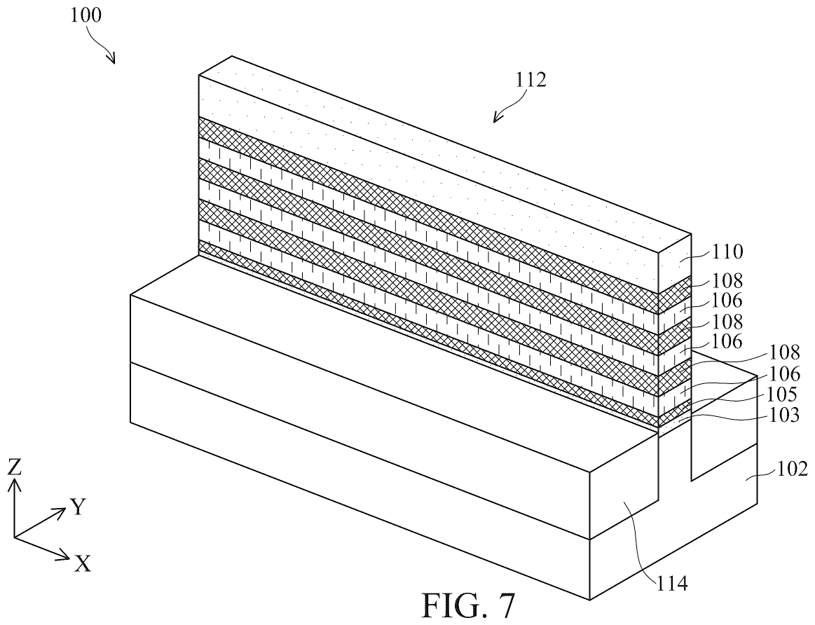

Referring to FIG. 7, isolation features 114 are formed over the substrate 102. In some aspects, the isolation features 114 are formed around the fin 112. More specifically, the isolation features 114 are formed on opposite sides of the fin 112 (the etch stop layer 103 and the semiconductor layers 105, 106, and 108) in the Y-direction. The isolation features 114 may be shallow trench isolation (STI) features that provide electrical isolation between the different GAA transistors, in accordance with some embodiments. As such, the isolation features 114 may also be referred to as STI features.

In some embodiments, a dielectric material for the isolation features 114 are first deposited over the workpiece 100. Specifically, the dielectric material is deposited and formed over the hard mask layer 110, the fin 112, and the substrate 102 to cover the hard mask layer 110, the fin 112, and the substrate 102. In some aspects, the dielectric material is formed to wrap around the fin 112. In some embodiments, the dielectric material may include silicon oxide, silicon nitride, silicon oxynitride, silicon carbide, borosilicate glass (BSG), phosphoric silicate glass (PSG), borophosphosilicate glass (BPSG), fluorine-doped silicate glass (FSG), a low-k dielectric (e.g., a carbon doped oxide, SiCOH), combinations thereof, and/or other suitable materials. In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process. The hard mask layer 110 is also removed during the planarization of the deposited dielectric material. The planarized dielectric material is further recessed by a dry etching process, a wet etching process, and/or a combination thereof to form the isolation features 114.

In some embodiments, the isolation features 114 may have a multi-layer structure such as a thermal oxide liner layer over the substrate 102 and a filling layer (e.g., silicon nitride or silicon oxide) over the thermal oxide liner layer. In some embodiments, before the formation of the isolation features 114, a liner layer may be conformally deposited over the substrate 102 using ALD or CVD. Furthermore, as shown in FIG. 7, the stack portion of the fin 112 rise above the isolation features 114 while the base fin 102-1 are surrounded by the isolation features 114.

In some embodiments, a top surface (or a topmost surface) of the substrate 102 is lower than top surfaces of the isolation features 114. In other words, the top surfaces of the isolation features 114 are higher than the top surface (or the topmost surface) of the substrate 102. Furthermore, the top surfaces of the isolation features 114 are higher than a bottom surface of the etch stop layer 103, and lower than a top surface of the etch stop layer 103 and a bottom surface of the semiconductor layer 105, as shown in FIG. 7. Therefore, the isolation features 114 are in contact with the semiconductor layer 105 of the fin 112, as shown in FIG. 7

Referring to FIG. 8, dummy gate structures 118-1 to 118-3 (may be collectively referred to as dummy gate structures 118) may be formed over the fin 112, the isolation feature 114, and the substrate 102. The dummy gate structures 118 may be configured to extend lengthwise in the Y-direction and wrap around a top surface and side surfaces of the fin 112, as shown in FIG. 8. In some embodiments, to form the dummy gate structures 118, a dummy interfacial material of a dummy interfacial layer 120 is first formed over fin 112 and the isolation features 114. In some embodiments, the dummy interfacial layer 120 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 122 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

Then, hard mask layers 124 are formed over the dummy gate material. In some embodiments, the hard mask layers 124 may be formed using photolithography and removal (e.g., etching) processes. In some embodiments, the hard mask layers 124 may include photoresist materials or hard mask materials. In some embodiments, each of the hard mask layers 124 may include multiple layers, such as a silicon nitride layer and a silicon oxide layer. After the formation of the hard mask layers 124, a removal process (e.g., etching) may be performed to remove portions of the dummy gate material for the dummy gate electrodes 122 and the dummy interfacial material for the dummy interfacial layers 120 that do not directly underlie the hard mask layers 124, thereby forming the dummy gate structures 118 each having the dummy interfacial layer 120, the dummy gate electrode 122, and the hard mask layer 124. The dummy interfacial layers 120 may also be referred to as dummy gate dielectrics. The dummy gate structures 118 may undergo a gate replacement process through subsequent processing to form metal gates, such as a high-k metal gate, as discussed in greater detail below.

FIG. 8 shows three dummy gate structures 118-1 to 118-3. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 118 from neighboring transistors or devices. For examples, dummy gate structures 118-1 and 118-3 may be replaced with dielectric material in sequent processes to form dielectric based gates to isolate resultant transistor formed from the dummy gate structure 118-2 from neighboring transistors or devices.

Referring to FIGS. 9A and 9B, after the formation of the dummy gate structures 118, the hard mask layers 124 are removed and gate spacers 126 are formed on the sidewalls of the dummy gate structures 118, over top surfaces of the fin 112, and on sidewalls of the fin 112 (not shown). More specifically, the gate spacers 126 are formed on opposite sidewalls of the fin 112 in the Y-direction (not shown) and formed on opposite sides (or sidewalls) of the dummy gate structures 118 in the X-direction, as shown in FIG. 9A.

The gate spacers 126 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 126 may include a single layer or a multi-layer structure. In some embodiments, the gate spacers 126 may be formed by conformally depositing a spacer layer (containing the dielectric material) over the isolation features 114, the fin 112, and dummy gate structures 118, followed by an anisotropic etching process to remove top portions of the spacer layer from the top surfaces of the isolation features 114, the fin 112, and dummy gate structures 118. After the etching process, portions of the spacer layer on the sidewall surfaces of the fin 112 (not shown) and the dummy gate structures 118 substantially remain and become the gate spacers 126. In some embodiments, the anisotropic etching process is a dry (e.g., plasma) etching process. Additionally or alternatively, the formation of the gate spacers 126 may also involve chemical oxidation, thermal oxidation, ALD, CVD, and/or other suitable methods.

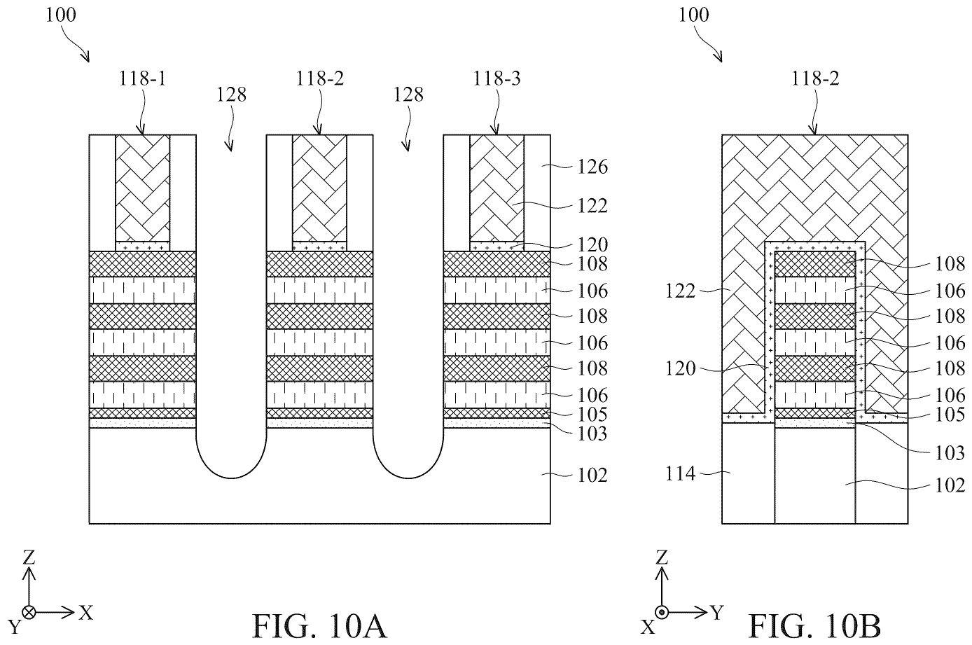

Referring to FIGS. 10A and 10B, the fin 112 is recessed to form source/drain trenches 128 in the fin 112 (or passing through the etch stop layer 103 and the semiconductor layers 105, 106, and 108) exposed by the dummy gate structures 118. More specifically, the source/drain trenches 128 are formed on opposite sides of the dummy gate structures 118 in the X-direction, as shown in FIG. 10A. The source/drain trenches 128 may be formed by performing one or more etching processes to remove portions of the semiconductor layers 106, the semiconductor layers 108, the semiconductor layer 105, the etch stop layer 103, and the substrate 102 that do not vertically overlap or be covered by the dummy gate structures 118 and gate spacers 126. In some embodiments, a single etchant may be used to remove the semiconductor layers 106, the semiconductor layers 108, the semiconductor layer 105, the etch stop layer 103, and the substrate 102, whereas in other embodiments, multiple etchants may be used to perform the etching process. As shown in FIG. 10A, portions of the substrate 102 are etched so that the substrate 102 has concave surfaces, and the concave surfaces are lower than the top surfaces of the isolation features 114 (not shown).

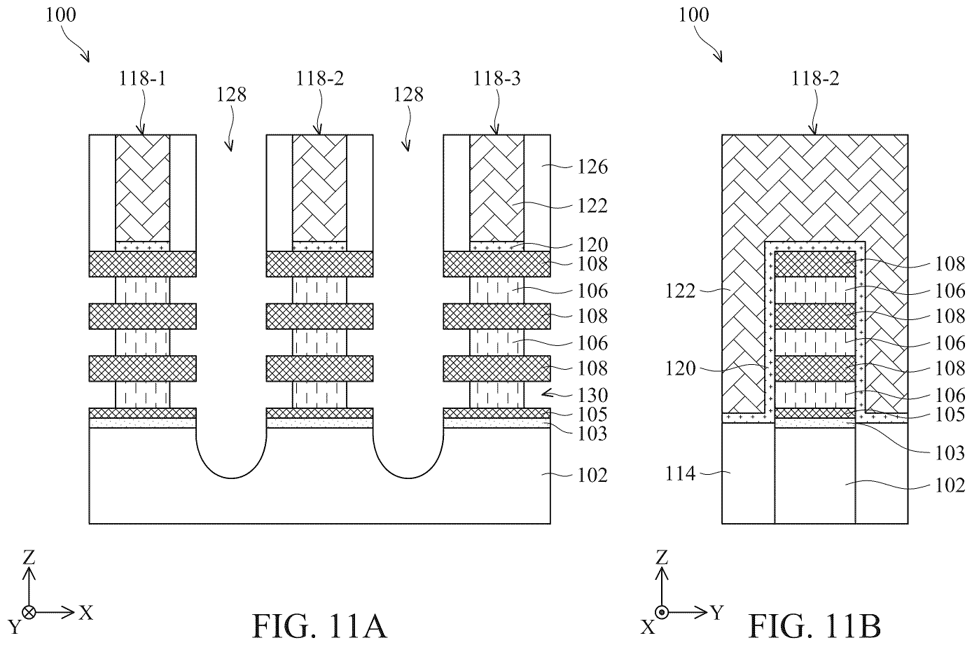

Referring to FIGS. 11A and 11B, side portions of the semiconductor layers 106 are removed via a selective etching process. More specifically, the selective etching process is performed that selectively etches the side portions of the semiconductor layers 106 below the gate spacers 126 through the source/drain trenches 128, with minimal (or no) etching of the gate spacers 126, the semiconductor layers 108, the semiconductor layer 105, the etch stop layer 103, and the substrate 102, such that gaps 130 are formed vertically between (the side portions of) the semiconductor layers 108 in the Z-direction as well as vertically between (the side portions of) the semiconductor layers 108 and the semiconductor layer 105 in the Z-direction, and below the gate spacers 126. The etching process is configured to laterally etch (e.g., along the X-direction) the semiconductor layers 106 below the gate spacers 126. The selective etching process is a dry etching process, a wet etching process, other suitable etching process, or combinations thereof.

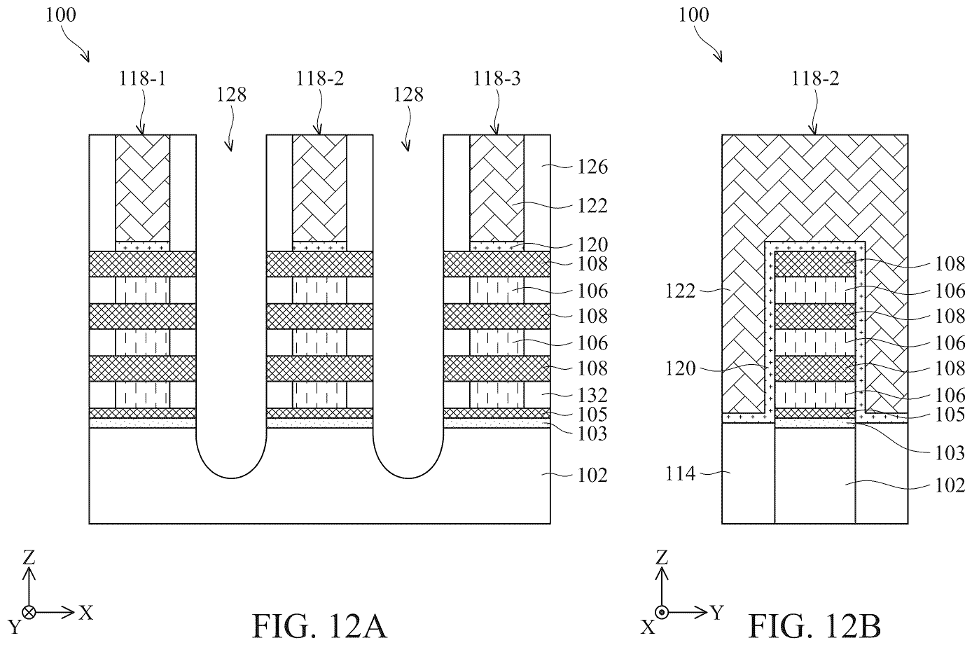

Referring to FIGS. 12A and 12B, inner spacers 132 are formed to fill the gaps 130. The inner spacers 132 are between the semiconductor layers 108 in the Z-direction and between the (bottommost) semiconductor layers 108 and the semiconductor layer 105 direct under the gate spacers 126 in the Z-direction. In some embodiments, sidewalls of the inner spacers 132 are aligned to the sidewalls of the gate spacers 126, the semiconductor layers 108, the semiconductor layer 105, and etch stop layer 103, as shown in FIG. 12A. In order to form the inner spacers 132, a deposition process forms a spacer layer into the source/drain trenches 128 and the gaps 130, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 128. The deposition process is configured to ensure that the spacer layer fills the gaps 130 between the semiconductor layers 108 as well as between the semiconductor layer 108 and the semiconductor layer 105 under the gate spacers 126. An etching process is then performed that selectively etches the spacer layer to form inner spacers 132 (as shown in FIG. 12A) with minimal (to no) etching of the semiconductor layer 108, the semiconductor layer 105, the etch stop layer 103, the substrate 102, the dummy gate structure 118, and the gate spacers 126. In sequent processes discussed in below, the inner spacers 132 will be removed and replaced with other inner spacers. Therefore, the inner spacers 132 may also be referred to as sacrificial inner spacers, in accordance with some embodiments.

The spacer layer (and thus inner spacers 132) includes a material that is different than a material of the semiconductor layers 108 and a material of the gate spacers 126 to achieve desired etching selectivity during the etching process. In some embodiments, the inner spacers 132 include a dielectric material that includes silicon, oxygen, carbon, nitrogen, other suitable material, or combinations thereof (for example, silicon oxide (SiOx), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). In some embodiments, the inner spacers 132 include a low-k dielectric material, such as those described herein.

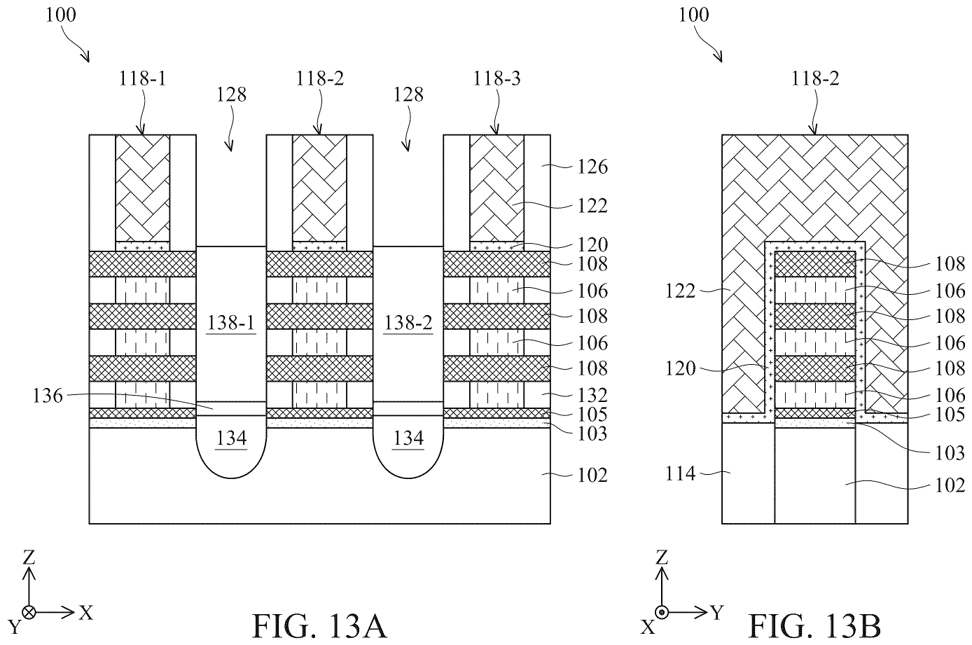

Referring to FIGS. 13A and 13B, epitaxial layers 134 are formed over the substrate 102 in the source/drain trenches 128. As shown in FIG. 13A, the epitaxial layers 134 are also formed on opposite sides of the dummy gate structures 118 (e.g., the dummy gate structure 118-2), the semiconductor layers 108, the semiconductor layers 106, the semiconductor layer 105, and etch stop layer 103 in the X-direction. In some embodiment, top surfaces of the epitaxial layers 134 are higher than the top surfaces of the substrate 102 and the top surfaces of the etch stop layer 103, in the X-Z cross-sectional view, as shown in FIG. 13A. In some embodiments, the top surfaces of the epitaxial layers 134 are lower than a top surface of the semiconductor layer 105. In some embodiment, the epitaxial layers 134 each has a convex bottom surface due to the concave surfaces of the substrate 102 in the source/drain trenches 128 discussed above.

The epitaxial layers 134 are made of silicon germanium without dopants. In other word, the epitaxial layers 134 include (un-doped) silicon germanium, and thus may be referred to as (un-doped) silicon germanium layers. One or more epitaxy processes may be performed to form the epitaxial layers 134. Epitaxy processes may implement CVD deposition techniques (for example, vapor-phase epitaxy (VPE), UHVCVD, LPCVD, and/or PECVD), molecular beam epitaxy, other suitable SEG processes, or combinations thereof.

Still referring to FIGS. 13A and 13B, bottom dielectric layers 136 are formed over the epitaxial layers 134 and the substrate 102 in the source/drain trenches 128. In some embodiment, the bottom dielectric layers 136 are in contact with the sidewalls of the semiconductor layer 105 and the etch stop layer 103 in the X-direction, in the X-Z cross-sectional view, as shown in FIG. 13A. In some aspect, the bottom dielectric layers 136 are in contact with and between the inner spacers 132 in the X-direction and in contact with the semiconductor layer 105 in the X-direction, in the X-Z cross-sectional view. In some embodiments, the top surfaces of the bottom dielectric layers 136 are higher than the top surface of the semiconductor layer 105 to ensure that the bottom dielectric layers 136 separate source/drain features 138 (will be discussed below) from the epitaxial layers 134 and the substrate 102. In some embodiments, top surfaces of the bottom dielectric layers 136 are lower than bottommost surfaces of the semiconductor layers 108, as shown in FIG. 13A.

In some embodiments, the dielectric material of the bottom dielectric layers 136 may include silicon nitride (Si₃N₄), such that the bottom dielectric layers 136 are also referred to as silicon nitride layers, and may be deposited by CVD, PVD, ALD, HDPCVD, MOCVD, RPCVD, PECVD, LPCVD, ALCVD, APCVD, other suitable methods, or combinations thereof. It should be noted that the source/drain features 138 are separated from the epitaxial layers 134 and the substrate 102 by the bottom dielectric layers 136.

Still referring to FIGS. 13A and 13B, source/drain features 138 (including source/drain features 138-1 and 138-8) are formed in the source/drain trenches 128 and over the bottom dielectric layers 136, the epitaxial layers 134, and the substrate 102, so that the source/drain features 138 pass through the semiconductor layers 108 and are in the fins 112. The source/drain features 138 are also formed on opposite sides of the dummy gate structures 118 in the X-direction. For example, the source/drain features 138 are formed on opposite sides of the dummy gate structure 118-2 in the X-direction, as shown in FIG. 13A. Furthermore, the source/drain features 138 are disposed on opposite sides of the semiconductor layers 108 in the X-direction. The source/drain features 138 are connected to and in contact with the semiconductor layers 108. More specifically, the source/drain features 138 are attached and electrically connected to the semiconductor layers 108 in the X-direction. As shown in FIG. 13A, the source/drain features 138 are also in contact with the inner spacers 132, but are electrically isolated from the inner spacers 132. In some aspects, the inner spacers 132 are disposed between the source/drain features 138 and the dummy gate structures 118 in the X-direction. Furthermore, the epitaxial layers 134 are between the source/drain features 138 and the substrate 102 in the Z-direction. The bottom dielectric layers 136 are between the source/drain features 138 and the epitaxial layers 134 in the Z-direction. In some aspect, the bottom dielectric layers 136 and the epitaxial layers 134 are under the source/drain features 138 and over the substrate 102. More specifically, the epitaxial layers 134 are vertically between and in contact with the bottom dielectric layers 136 and the substrate 102 in the Z-direction and the bottom dielectric layers 136 are vertically between and in contact with the source/drain features 138 and the epitaxial layers 134 in the Z-direction.

In some aspects, the semiconductor layers 108 serve as channels to connect one source/drain feature 138 (e.g., the source/drain feature 138-1) to the other source/drain feature 138 (e.g., the source/drain feature 138-2). Therefore, the semiconductor layers 108 may also be referred to as channels, channel layers, or channel members. In some embodiments, in the X-Z cross-sectional view shown in FIG. 13A, the source/drain features 138 may have top surfaces that extend higher than top surfaces of the topmost semiconductor layers 108 (e.g., in the Z-direction), as shown in FIG. 13A. In some embodiments, in the X-Z cross-sectional view shown in FIG. 13A, the source/drain features 138 may have the top surfaces that extend higher than bottom surfaces of the dummy interfacial layers 120 (e.g., in the Z-direction). In other embodiments, the top surfaces of the source/drain features 138 are substantially level with the top surfaces of the topmost semiconductor layers 108 (i.e., substantially coplanar).

One or more epitaxy processes may be employed to grow the source/drain features 138. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 138 may include any suitable semiconductor materials. For example, the source/drain features 138 used for n-type GAA transistors may include epitaxially-grown material selected from a group consisting of silicon phosphide (SiP), silicon carbide (SiC), silicon phosphoric carbide (SiPC), silicon arsenide (SiAs), silicon (Si), or a combination thereof. In some embodiments, the epitaxially-grown material of the source/drain features 138 may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 138 for n-type GAA transistors may respectively be referred to as n-type source/drain features.

The source/drain features 138 used for p-type GAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 138 may be doped with p-type dopants (such as boron, indium, other p-type dopant, or a combination thereof) having a doping concentration in a range from about 1×10¹⁹/cm³ to 6×10²⁰/cm³. In some embodiments, the source/drain features 138 for p-type GAA transistors may respectively be referred to as p-type source/drain features.

The source/drain features 138 may also be referred to as source/drain, or source/drain regions. In some embodiments, source/drain feature(s) 138 may refer to a source or a drain, individually or collectively dependent upon the context. The source/drain features 138 may be doped in-situ or ex-situ. One or more annealing processes may be performed to activate the dopants in the source/drain features 138. The annealing processes may include rapid thermal annealing (RTA) and/or laser annealing processes.

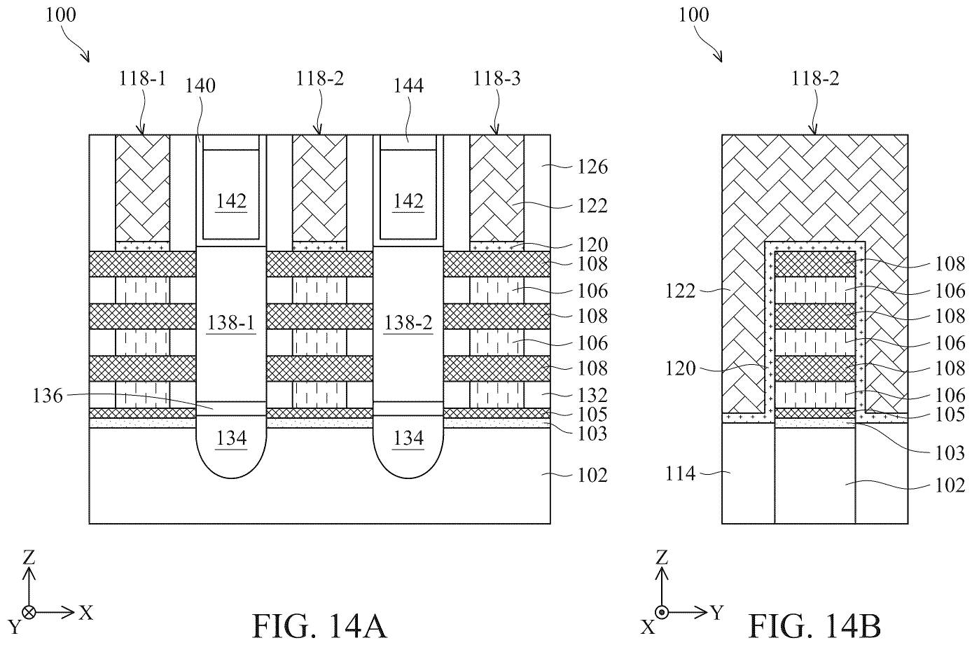

Referring to FIGS. 14A and 14B, a contact etch stop layer (CESL) 140 over the source/drain features 138 and an interlayer dielectric (ILD) layer 142 over the CESL 140 are formed to fill the spaces between the gate spacers 126 and in the source/drain trenches 128. Specifically, the CESL 140 is conformally formed on the sidewalls of the gate spacers 126, over the top surfaces of the source/drain features 138, as shown in FIG. 14A. The ILD layer 142 is then formed over the CESL 140 to fill a remaining space between (or inside) the CESL 140, between the gate spacers 126 and in the source/drain trenches 128.

The CESL 140 includes a material that is different than ILD layer 142. The CESL 140 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 142 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 142 may be formed by PECVD (plasma enhanced CVD), FCVD (flowable CVD), or other suitable methods.

Subsequent to the deposition of the CESL 140 and the ILD layer 142, a CMP process and/or other planarization process is performed on the CESL 140 and the ILD layer 142 until the top surfaces of the dummy gate electrodes 122 and the gate spacers 126 are exposed. In some embodiments, portions of the dummy gate electrodes 122 are removed after the planarization process. In some embodiments, the ILD layer 142 is recessed to a level below the top surface of the dummy gate electrode 122, and then an ILD protection layer 144 is formed over the ILD layer 142 to protect the ILD layer 142 from subsequent etching processes. As such, the ILD layer 142 is surrounded by the CESL 140 and the ILD protection layer 144. In some embodiments, the ILD protection layer 144 includes a material that is the same as or similar to that in the CESL 140. In some other embodiments, the ILD protection layer 144 includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

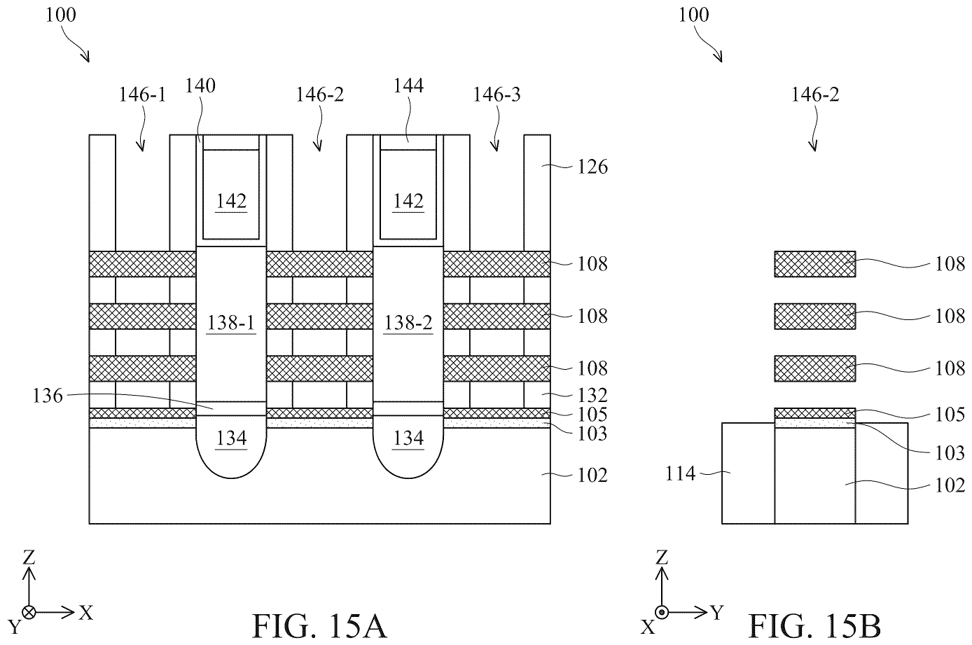

Referring to FIGS. 15A and 15B, the dummy gate structures 118 are selectively removed through any suitable lithography and etching processes to form gate trenches 146 (including gate trenches 146-1 to 146-3). In some embodiments, the lithography process may include forming a photoresist layer (resist), exposing the resist to a pattern, performing a post-exposure bake process, and developing the resist to form a masking element, which exposes a region including the dummy gate structures 118. Then, the dummy gate structures 118 are selectively etched through the masking element. The gate spacers 126 may be used as the masking element or a part thereof. Etch selectivity may be achieved by selecting the appropriate etching chemicals, and the dummy gate structures 118 may be removed without substantially affecting the CESL 140, the ILD layer 142, and the ILD protection layer 144. The removal of the dummy gate structures 118 creates the gate trenches 146-1 to 140-3, in which the gate trenches 146-1 to 140-3 expose the top surfaces of the fins 112 (specifically, the top surfaces of the topmost semiconductor layers 108).

Still referring to FIGS. 15A and 15B, the semiconductor layers 106 of the fins 112 are selectively removed through the gate trenches 146, using a wet or dry etching process for example, so that middle portions of the semiconductor layers 108 are exposed in the gate trenches 146 to form nanostructures stacked over each other, which serving as channels, channel layers, or channel members for resultant transistors. As such, the semiconductor layers 108 may be referred to as nanostructures. Specifically, the semiconductor layers 108 are stacked over each other in the Z-direction. Such a process may also be referred to as a release process, a channel release process, a wire release process, a nanowire release process, a nanosheet release process, a nanowire formation process, a nanosheet formation process, or a wire formation process.

In some embodiments, the removal of the semiconductor layers 106 causes the exposed semiconductor layers 108 to be spaced apart from each other in the vertical direction (e.g., in the Z-direction). The exposed semiconductor layers 108 extend longitudinally in the horizontal direction (e.g., in the X-direction). Furthermore, each of the semiconductor layers 108 connects one source/drain feature 138 (e.g., the source/drain feature 138-1) to another source/drain feature 138 (e.g., the source/drain feature 138-2), as shown in FIG. 15A). In some embodiments, thicknesses of the semiconductor layers 108 exposed in the gate trenches 146 may be reduced during the removal of the semiconductor layers 106.

As discussed above, the semiconductor layer 105 is formed over the etch stop layer 103. The semiconductor layer 105 protect the etch stop layer 103 during the removal of the semiconductor layers 106. Therefore, the semiconductor layers 106 are removed without substantial damages to the etch stop layer 103, thereby the etch stop layer 103 may protect the other features (e.g., gate structures) during the removal of the substrate 102 in sequent processes. As discussed above, the thickness of the semiconductor layer 105 is greater than 1 nm. If the thickness of the semiconductor layer 105 is less than 1 nm, the semiconductor layer 105 may be able to protect the etch stop layer 103 during the removal of the semiconductor layers 106.

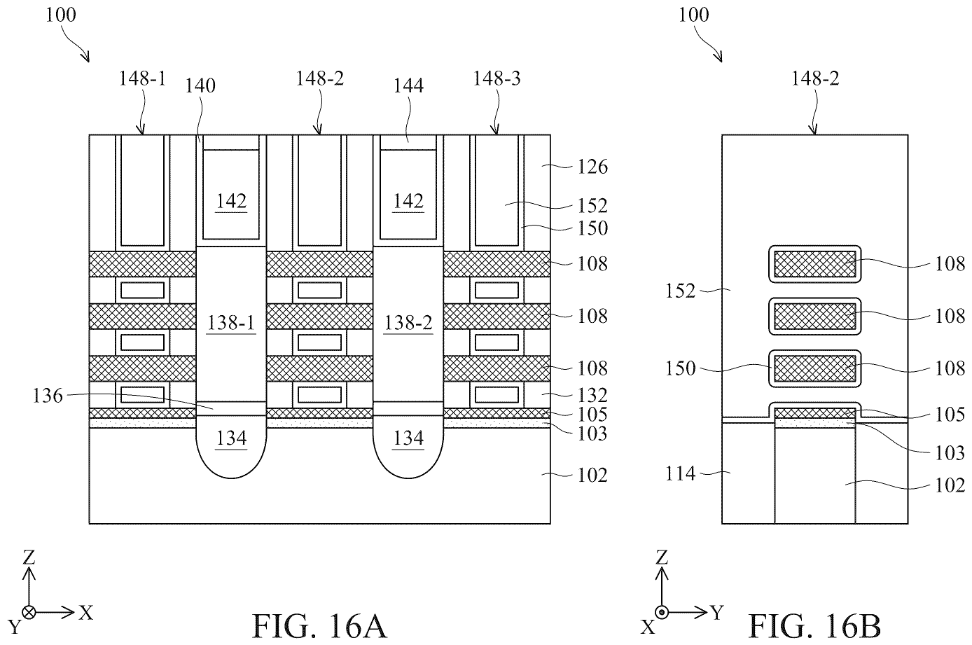

Referring to FIGS. 16A and 16B, gate structures 148 (including gate structures 148-1 to 148-3) are formed in the gate trenches 146 to wrap around the exposed semiconductor layers 108. As such, the gate structures 148 replace the dummy gate structures 118. In some embodiments, the gate structures 148 extend in the Y-direction (as shown in FIG. 16B). As shown in FIG. 16A, the source/drain features 138 are formed on opposite sides of the gate structure 148-2 in the X-direction. The gate structures 148 each includes a gate dielectric layer 150 and a gate electrode layer 152 over the gate dielectric layer 150. In some embodiments, the gate dielectric layers 150 are formed to wrap around the semiconductor layers 108 in the gate trenches 146. Additionally, the gate dielectric layers 150 also formed on the sidewalls of the inner spacers 132 and the gate spacers 126. Furthermore, the gate dielectric layers 150 are also formed over the etch stop layer 103 and the semiconductor layer 105 and on sidewalls of the etch stop layer 103 and the semiconductor layer 105 in the Y-direction, as shown in FIG. 16B.

The gate dielectric layers 150 may include a dielectric material having a dielectric constant greater than a dielectric constant of SiO₂, which is approximately 3.9. For example, the gate dielectric layers 150 may include hafnium oxide (HfO₂), which has a dielectric constant in a range from about 18 to about 40. Alternatively, the gate dielectric layers 150 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 150 may be formed by ALD, PVD, CVD, oxidation, and/or other suitable methods.

In some embodiments, the gate structures 148 each may further include interfacial layer formed to wrap around the exposed semiconductor layers 108 before the formation of the gate dielectric layers 150, so that the gate dielectric layers 150 are separated from semiconductor layers 108 by the interfacial layer. In some embodiments, the interfacial layer may include a dielectric material such as silicon oxide (SiO₂), HfSiO, or silicon oxynitride (SiON). The interfacial layer may be formed by chemical oxidation, thermal oxidation, ALD, CVD, and/or other suitable method.

The gate electrode layers 152 are formed to fill the remaining spaces of the gate trenches 146, and over the gate dielectric layers 150 in such a way that the gate electrode layers 152 wrap around the semiconductor layers 108, the gate dielectric layers 150, and the interfacial layers (if present). The gate electrode layers 152 each may include a single layer or alternatively a multi-layer structure. In some embodiments, the gate electrode layers 152 each may include a capping layer, a barrier layer, work function metal layers, and a fill material.

The capping layer may be formed adjacent to the gate dielectric layers 152 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The gate electrode layers 152 may each has single or multiple work function metal materials. In some embodiments, the gate electrode layers 152 may each has n-type work function metal layers for n-type GAA transistors and p-type work function metal layers for p-type GAA transistors. More specifically, the gate electrode layers 152 may each has n-type work function metal layers between the source/drain features 138 with n-type dopant for n-type GAA transistors and p-type work function metal layers between the source/drain features 138 with p-type dopant for p-type GAA transistors, in accordance with some embodiments of the present disclosure.

The n-type work function metal layer may be formed adjacent to the barrier layer. In an embodiment, the n-type work function metal layer is a material such as Ti, Al, Ag, Mn, Zr, TiAl, TiAIC, TaC, TaCN, TaSiN, TaAl, TaAIC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

The p-type work function metal layer may be formed adjacent to the n-type work function metal layer. In an embodiment, the p-type work function metal layer may be a material such as TiN, TaN, Ru, Mo, Al, WN, ZrSi₂, MoSi₂, TaSi₂, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-type work function metal layer may be deposited using a deposition process such as ALD, CVD, or the like, although any suitable deposition process may be used.

Therefore, as shown in FIGS. 16A and 16B, the gate structures 148 including the gate dielectric layers 150 and the gate electrode layers 152 are formed to fill the gate trenches 146, thereby replacing the dummy gate structures 118 and the semiconductor layers 106. In some embodiments, the gate structures 148 are also formed over and in contact with the semiconductor 105 and the isolation features 114, as shown in FIGS. 16A and 16B. Furthermore, the gate structures 148 are also formed on and in contact with the sidewalls of the sidewalls of the etch stop layer 103 and the semiconductor layer 105 in the Y-direction, as shown in FIG. 16B. It is noted that the semiconductor layer 105 and the etch stop layer 103 are under the gate structures 148 to protect bottom surfaces of the gate structures 148 from the removal of the substrate 102 in sequent processes.

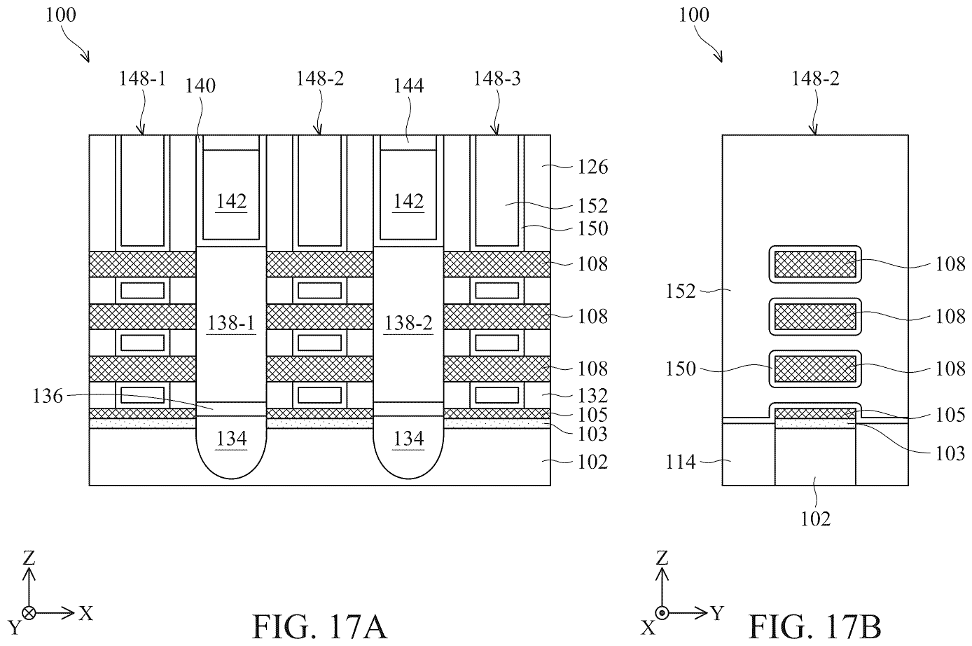

After the formation of the gate structures 148, the workpiece 100 may be flipped to form a back-side interconnection structure. For the purpose of simplicity, the sequent figures are shown without being flipped. Referring to FIGS. 17A and 17B, a CMP process and/or other planarization process is performed on a bottom surface of the substrate 102 to remove a portion of the substrate 102. In other words, the substrate 102 is thinned (i.e., the thickness of the substrate 102 is reduced) by the CMP process and/or other planarization process. As shown in FIG. 17B, bottom surfaces of the isolation features 114 are exposed after the CMP process. In some embodiments, portions of the isolation structure 202 may be removed (specifically, be thinned) during the CMP process. Such CMP process and/or other planarization process is used for reducing the thickness of the substrate 102 to facilitate the removal of the substrate 102 in a selective etching process.

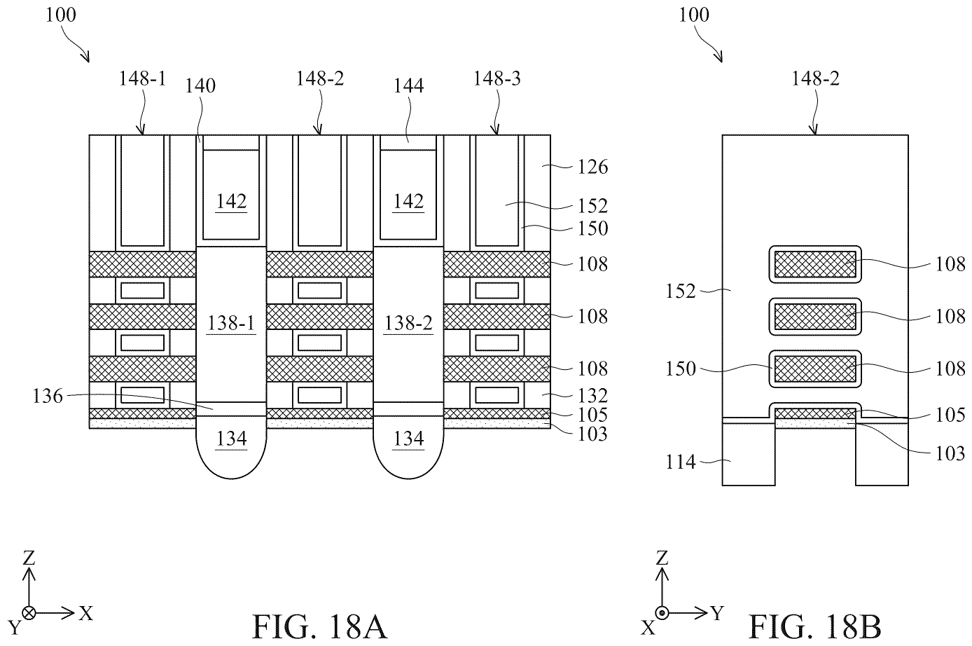

Referring to FIGS. 18A and 18B, the substrate 102 is removed from the workpiece 100 by the selective etching process. More specifically, the selective etching process is performed that selectively etches the substrate 102, with minimal (or no) etching of the epitaxial layers 134 and the etch stop layer 103. In order to remove the substrate 102, the selective etching process includes two methods to choose from. One method is to use chlorine gas (e.g., F₂) and amine (e.g., NH₃) as catalyst to remove the substrate 102, and the other method is to use NF radical from nitrogen trifluoride (NF₃) and sulfur hexafluoride (SF₆) in a plasma etching process. With the above methods, there is high etch selectivity of the substrate 102 to the etch stop layer 103 (e.g., 10). As discussed above, due to the etch stop layer 103 is under the gate structures 148, the etch stop layer 103 protect the gate structures 148 from the removal of the substrate 102 to prevent fluorination of the gate structures 148 during the selective etching process. Therefore, after the removal of the substrate 102, bottom surfaces of the etch stop layer 103 and the epitaxial layers 134 are exposed.

As discussed above, the thickness of the etch stop layer 103 is in a range from about 1 nm to about 3 nm. If the thickness of the etch stop layer 103 is less than 1 nm, the etch stop layer may not to goodly protect the gate structures 148. If the thickness of the etch stop layer 103 is greater than 3 nm, there may be more costs in the formation of the source/drain trenches 128 (because to the thickness of the etch stop layer 103 is too thick).

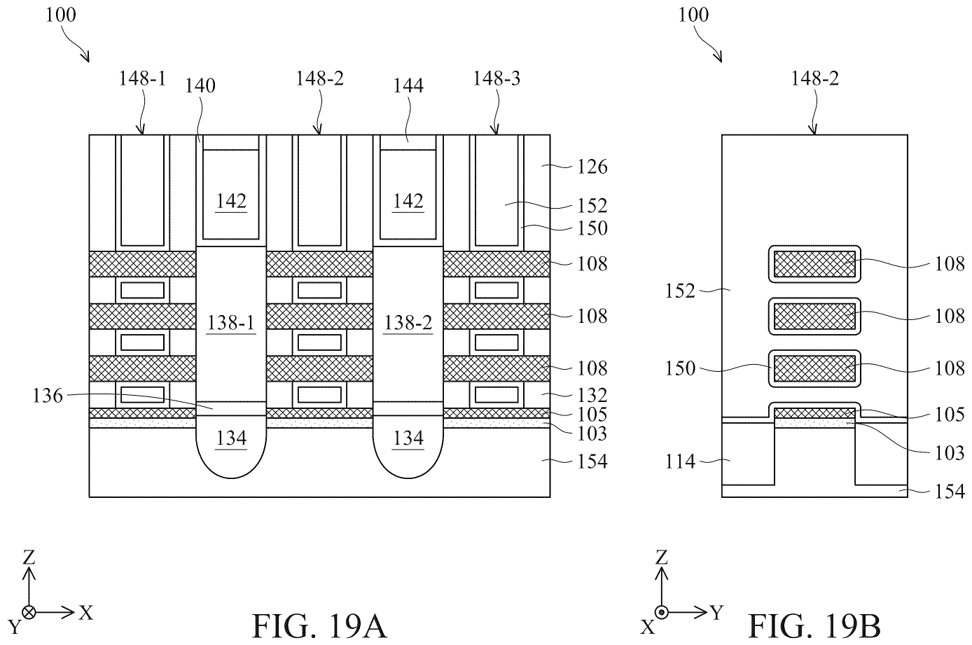

Referring to FIGS. 19A and 19B, after the removal of the substrate 102, a dielectric layer 154 is formed under the gate structures 148, the semiconductor layers 108, the source/drain features 138, the bottom dielectric layers 136, the epitaxial layers 134, the semiconductor layer 105, the etch stop layer 103, and the isolation features 114. More specifically, the dielectric layer 154 is formed under and in contact with the etch stop layer 103 and the epitaxial layers 134. Therefore, the substrate 102 is replaced with the dielectric layer 154, as shown in FIGS. 19A and 19B. The dielectric layer 154 includes a dielectric material, such as Si₃N₄, SiO₂, SiC, SiOC, SiON, SiCN, SiOCN, carbon doped oxide, nitrogen doped oxide, porous oxide, or combinations thereof.

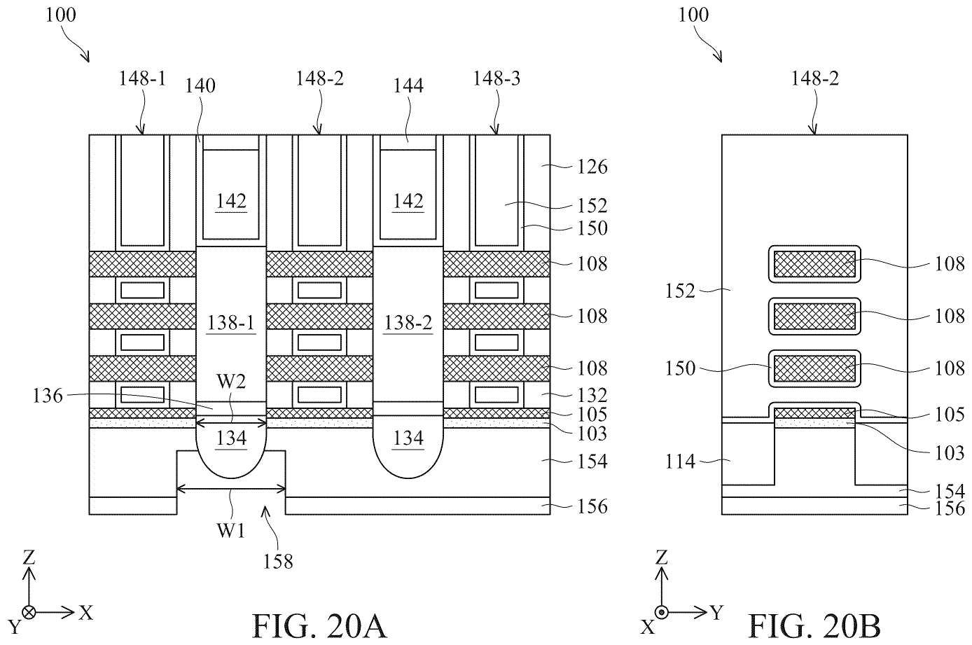

Referring to FIGS. 20A and 20B, an oxide layer 156 is formed under and in contact with the dielectric layer 154. In some embodiments, the oxide layer 156 is used as a hard mask layer. After the formation of the oxide layer 156, an opening 158 is formed passing through the oxide layer 156 and in the dielectric layer 154. More specifically, portions of the oxide layer 156 and the dielectric layer 154 are removed through any suitable lithography and etching processes to form the opening 158. As shown in FIG. 20A, a bottom surface of one the epitaxial layer 134 is exposed in the opening 158. It is noted that the opening 158 is formed without passing through the dielectric layer 154. Furthermore, a width W1 of the opening 158 in the X-direction is greater than a width W2 of the epitaxial layer 134 in the X-direction, as shown in FIG. 20A. This means that the width W2 of the opening 158 does not need to match the width W1 of the epitaxial layer 134, and the larger opening 158 can be used, which has a larger process window and is less affected by process variation.

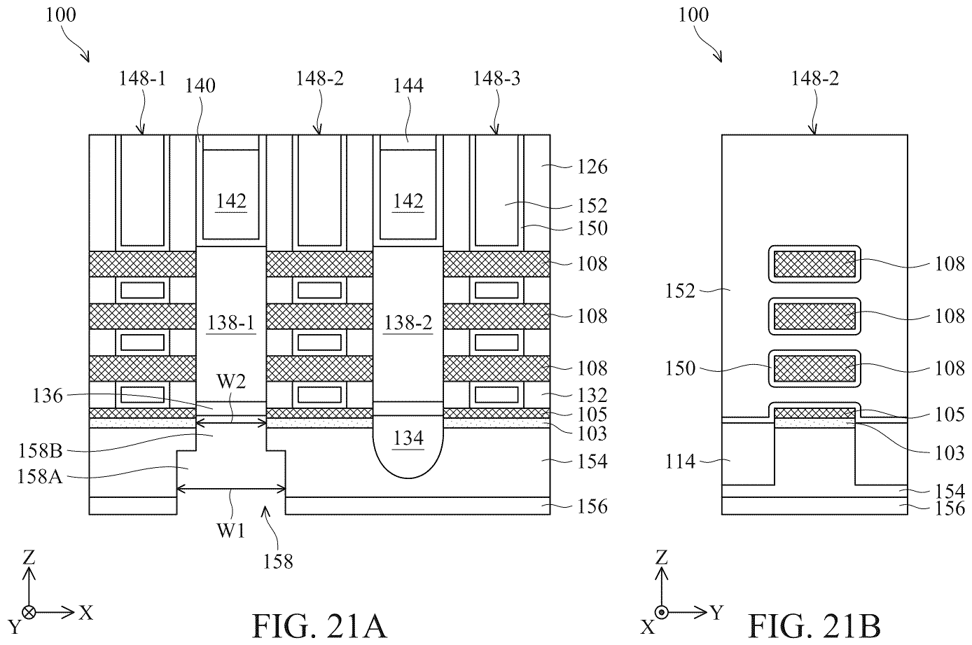

Referring to FIGS. 21A and 21B, the epitaxial layer 134 exposed in the opening 158 is removed. More specifically, the epitaxial layer 134 is removed via a selective etching process. The selective etching process is performed that selectively etches the epitaxial layer 134 exposed in the opening 158, with minimal (or no) etching of the dielectric layer 154, the etch stop layer 103, the semiconductor layer 105, and the bottom dielectric layer 136. As such, after the removal of the epitaxial layer 134 exposed in the opening 158, the opening 158 is enlarged to further expose a bottom surface of the bottom dielectric layer 136. The enlarged opening 158 has a first portion 158A and a second portion 158B over the first portion 158A, as shown in FIG. 21A. The second portion 158B is formed by selective etching of the epitaxial layer 134 exposed in the opening 158, such that the second portion 158B of the opening 158 is self-aligned. Therefore, the second portion 158B also has a width W2 in the X-direction as the epitaxial layer 134. In other words, the width W1 of the first portion 158A in the X-direction is greater than the width W2 of the second portion 158B in the X-direction, as shown in FIG. 21A.

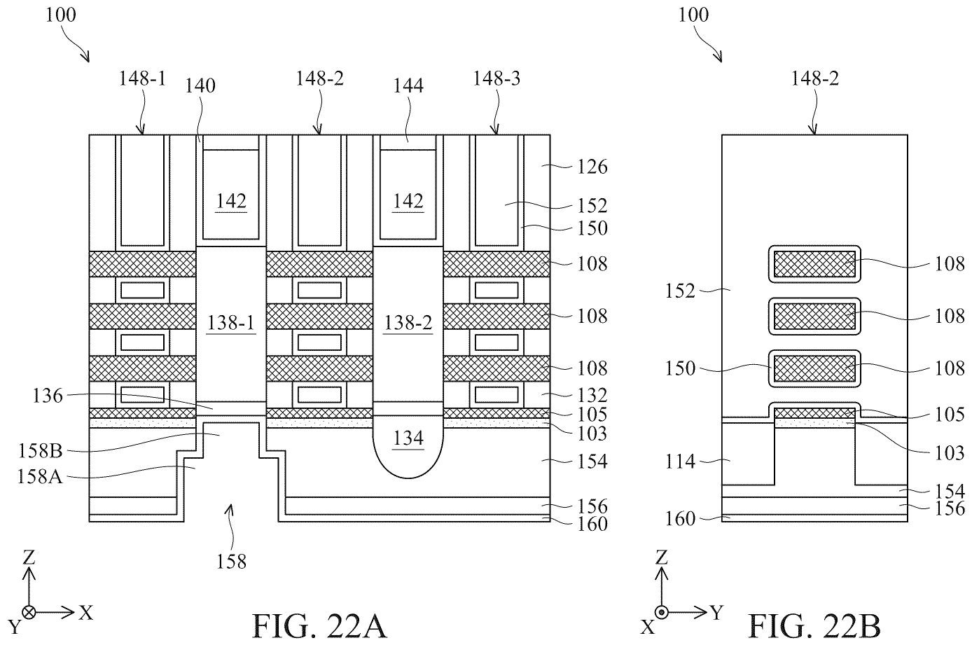

Referring to FIGS. 22A and 22B, a liner layer 160 is conformally formed in the opening 158. More specifically, the liner layer 160 is conformally formed under the oxide layer 156, on the sidewalls of the semiconductor layer 105, the etch stop layer 103, the dielectric layer 154 exposed in the opening 158, and under the bottom dielectric layer 136 exposed in the opening 158, as shown in FIG. 22A. In some embodiments, the liner layer 160 includes silicon nitride (Si₃N₄), and thus may be referred to as silicon nitride layer or silicon nitride liner.

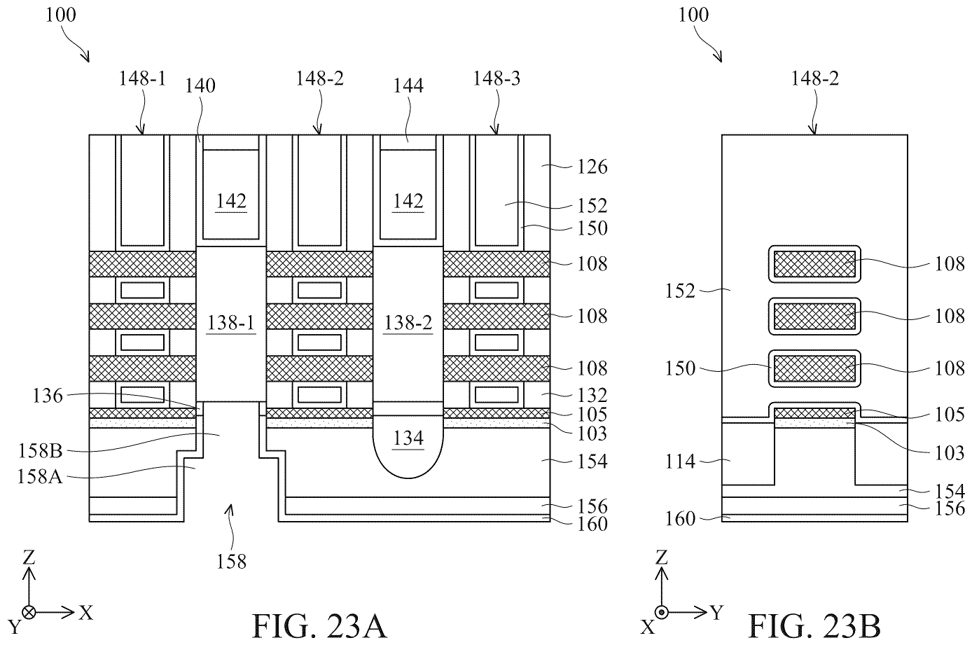

Referring to FIGS. 23A and 23B, a portion of the liner layer 160 under and in contact with the bottom dielectric layer 136 is removed. Then, a portion of the bottom dielectric layer 136 under and in contact with the source/drain feature 138-1 is removed. Therefore, as shown in FIG. 23A, a bottom surface of the source/drain feature 138-1 is exposed in the (enlarged) opening 158. The portion of the liner layer 160 and the portion of the bottom dielectric layer 136 are removed through any suitable lithography and etching processes. In some embodiments, a single etchant may be used to remove the portion of the liner layer 160 and the portion of the bottom dielectric layer 136, whereas in other embodiments, multiple etchants may be used to perform the etching process. The etching process may include dry etching, wet etching, reactive ion etching (RIE), and/or other suitable processes.

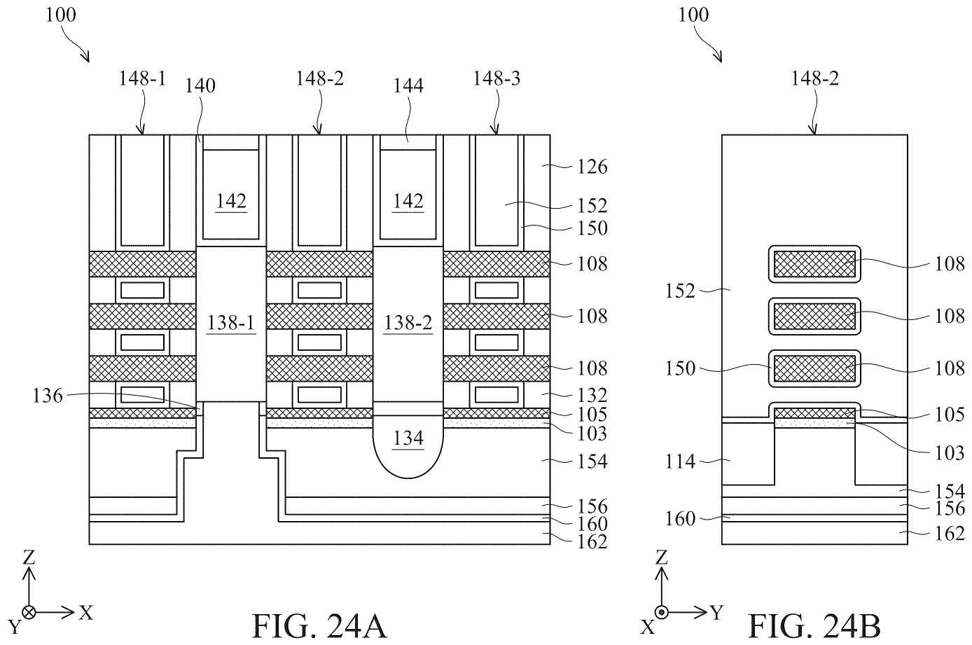

Referring to FIGS. 24A and 24B, a conductive material 162 is formed to fill the opening 158 and under the dielectric layer 154, the oxide layer 156, and the liner layer 160. The conductive material may be selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof.

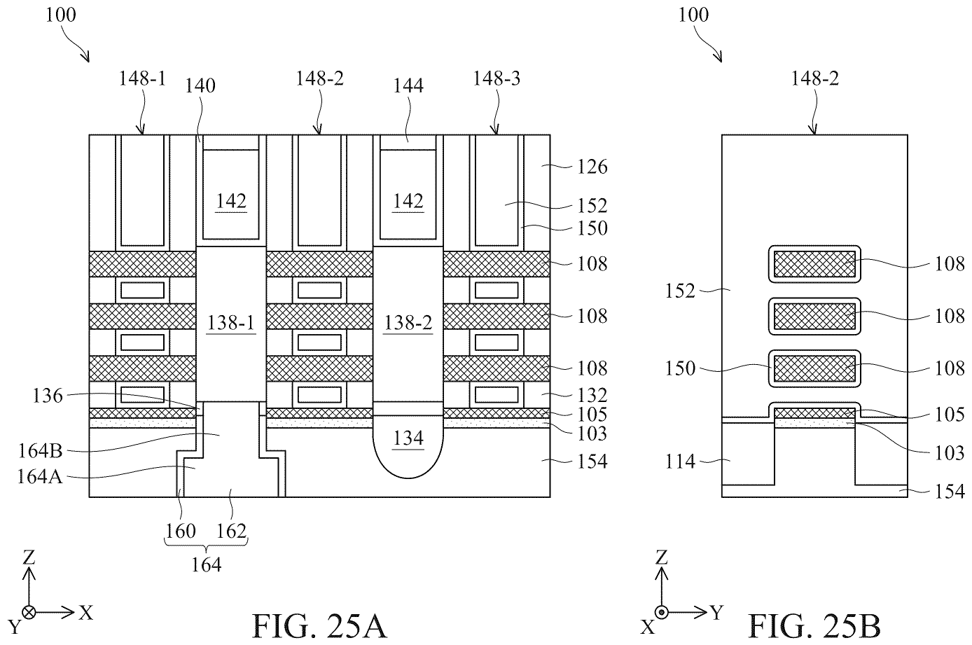

Referring to FIGS. 25A and 25B, a CMP process and/or other planarization process is performed on a bottom surface of the conductive material 162 to remove extra portions of the conductive material 162 and the liner layer 160 outside the opening 158 until a bottom surface of the dielectric layer 154 is exposed. In some embodiments, the bottom surfaces of the dielectric layer 154, the conductive material 162, and the liner layer 160 are substantially level with each other (i.e., substantially coplanar) after the CMP process, as shown in FIG. 25A.

Furthermore, after the CMP process, a via 164 including the conductive material 162 and the liner layer 160 is formed in the opening 158. As such, the portion of the dielectric layer 154 and the epitaxial layer 134 (under the source/drain feature 138-1) are replaced with the via 164. As shown in FIG. 25A, the via 164 is also formed passing through the dielectric layer 154, the etch stop layer 103, the semiconductor layer 105, and the bottom dielectric layer 136. In some embodiments, the via 164 is formed under and in contact with the source/drain feature 138-1. Specifically, the via 164 is formed electrically connected to the source/drain feature 138-1. Due to the shape of the (enlarged) opening 158, the via 164 also has a narrow portion 164B and a wider portion 164A under the narrow portion 164B. As shown in FIG. 25A, a width of the wider portion 164A in the X-direction is greater than a width of the narrow portion 164B in the X-direction. In some embodiments, the via 164 is formed on backside of the workpiece 100, and thus may be referred to as backside via.

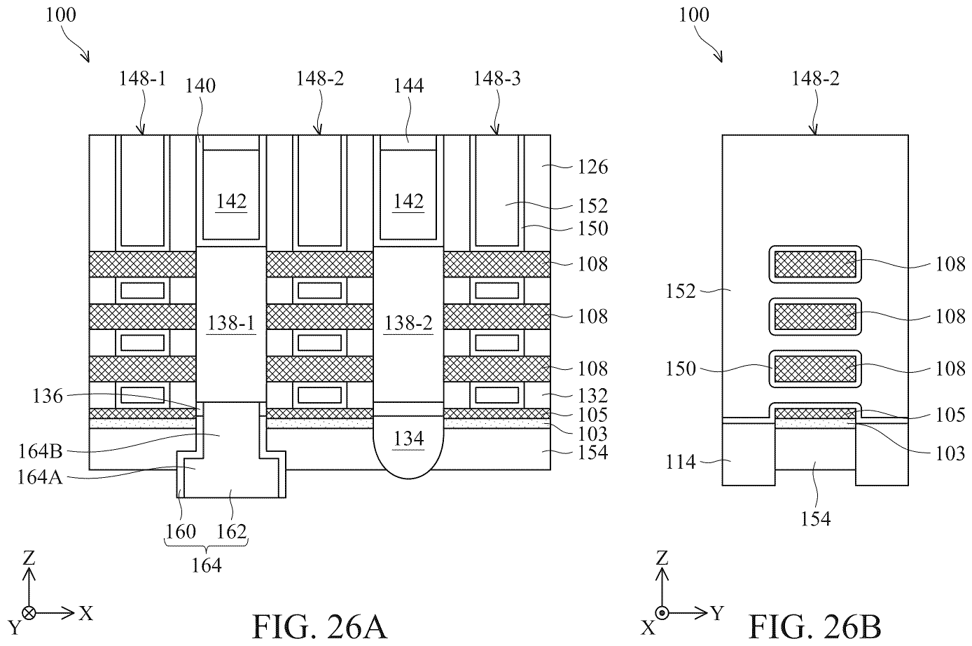

Referring to FIGS. 26A and 26B, after the CMP process for forming the via 164, the dielectric layer 154 is partially recessed to expose the epitaxial layer 134 under the source/drain feature 138-2 and the source/drain feature. More specifically, a selective etching process is performed that selectively etches the dielectric layer 154 to partially recess and remove portions of the dielectric layer 154, with minimal (or no) etching of the via 164, the epitaxial layer 134, and the isolation features 114, until bottom surfaces of the epitaxial layer 134 under the source/drain feature 138-2 and the isolation features 114 are exposed. The selective etching process is a dry etching process, a wet etching process, other suitable etching process, or combinations thereof.

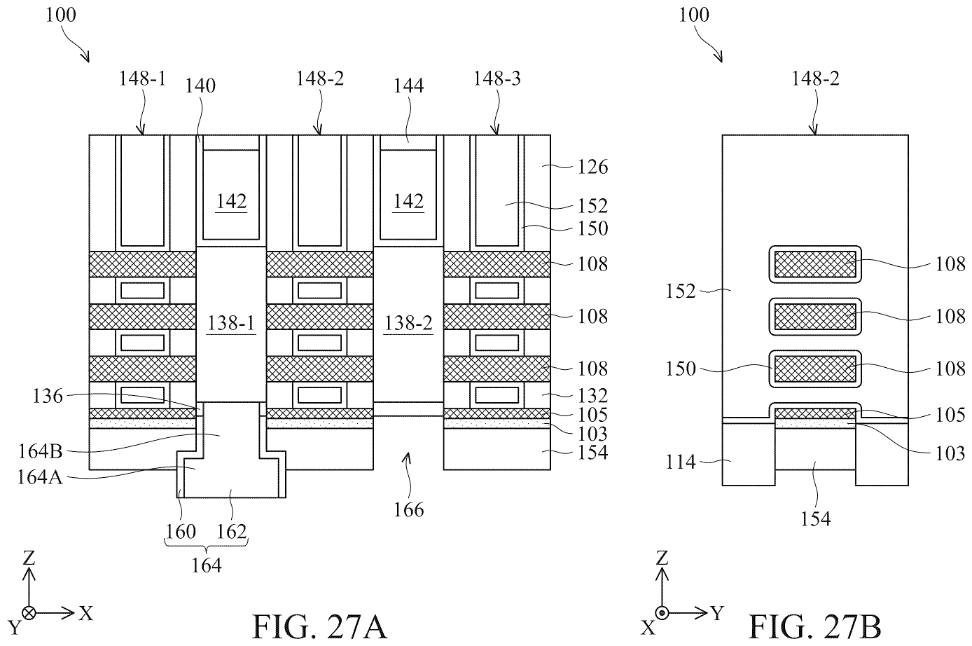

Referring to FIGS. 27A and 27B, the epitaxial layer 134 under the source/drain feature 138-2 is removed. More specifically, the epitaxial layer 134 under the source/drain feature 138-2 is removed via a selective etching process. The selective etching process is performed that selectively etches the epitaxial layer 134 under the source/drain feature 138-2 to form an opening 166 exposing the bottom dielectric layer 136 under the source/drain feature 138-2, with minimal (or no) etching of the dielectric layer 154, the etch stop layer 103, the semiconductor layer 105, and the bottom dielectric layer 136. The selective etching process is a dry etching process, a wet etching process, other suitable etching process, or combinations thereof.

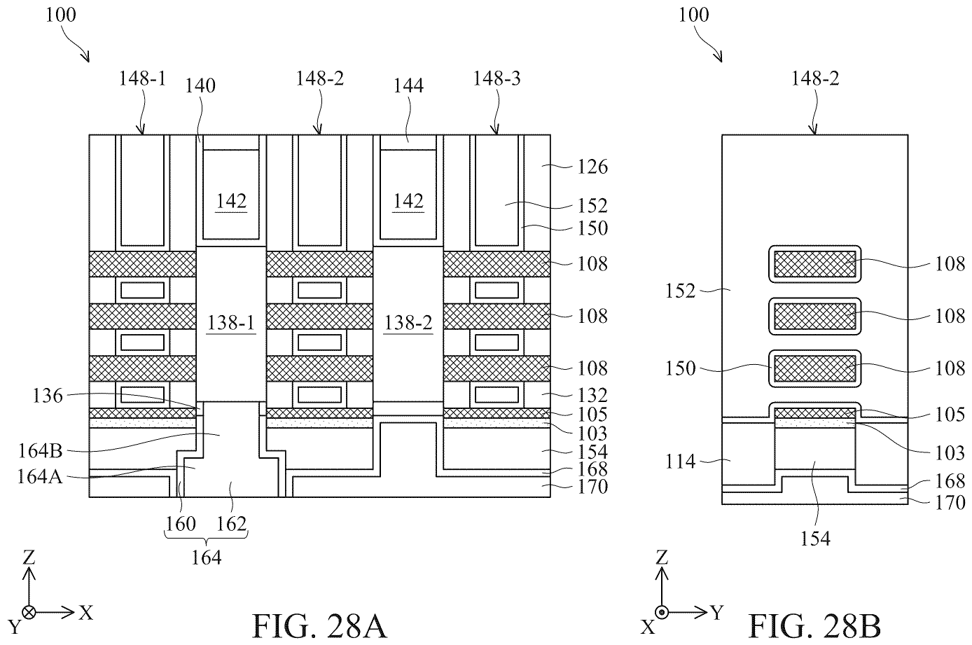

Referring to FIGS. 28A and 28B, a liner layer 168 and a dielectric layer 170 are formed after the removal of the epitaxial layer 134 under the source/drain feature 138-2. More specifically, the liner layer 168 is conformally formed under and in contact with the dielectric layer 154 and the isolation features 114, on and in contact with the sidewalls of the semiconductor layer 105, the etch stop layer 103, and the dielectric layer 154 exposed in the opening 166, and under and in contact with the bottom dielectric layer 136 exposed in the opening 166, as shown in FIG. 28A. Furthermore, the liner layer 168 is also conformally formed on sidewalls of the via 164 (specifically, the liner layer 160). In some embodiments, the liner layer 168 includes silicon nitride (Si₃N₄), and thus may be referred to as silicon nitride layer or silicon nitride liner.

Still referring to FIGS. 28A and 28B, after the formation of the liner layer 168, a dielectric later 170 is formed under the gate structures 148, the semiconductor layers 108, the source/drain feature 138-2, the bottom dielectric layers 136, the semiconductor layer 105, the etch stop layer 103, the dielectric layer 154, the isolation features 114, and the liner layer 160. The dielectric layer 170 includes a dielectric material, such as Si₃N₄, SiO₂, SiC, SiOC, SiON, SiCN, SiOCN, carbon doped oxide, nitrogen doped oxide, porous oxide, or combinations thereof. In some embodiments, the dielectric layers 154 and 170 have the same material. In other embodiments, the dielectric layers 154 and 170 have different materials.

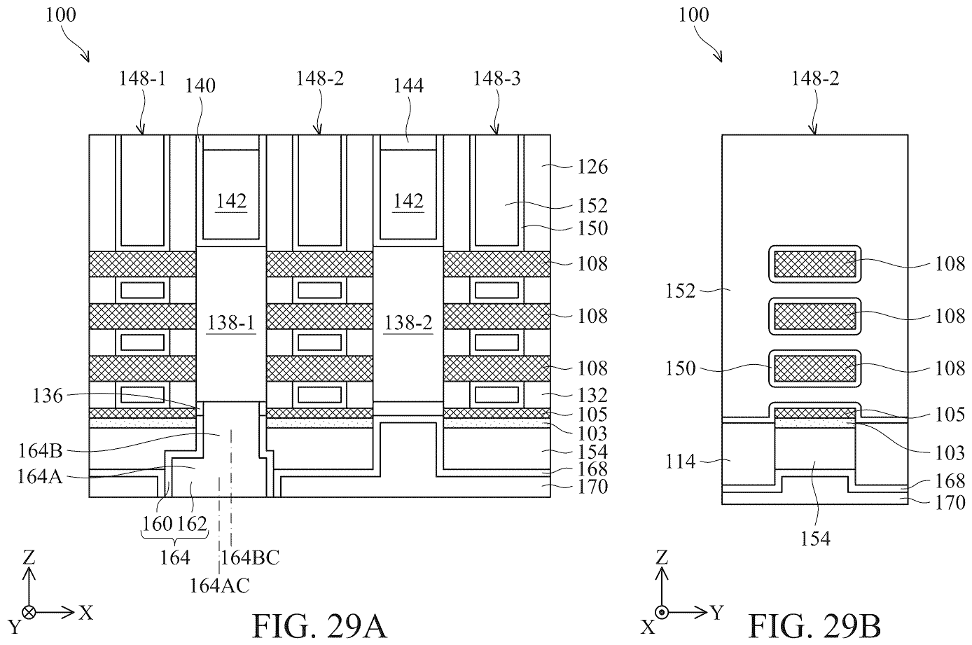

FIGS. 29A and 29B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. Referring back to FIGS. 28A and 28B, the via 164 is an asymmetric shape in the X-Z cross-sectional view. As discussed above, the method of forming the via 164 has a larger process window (because the opening 158 discussed above). Therefore, even if there is process variation in the formation of the via 164, the via 164 can still be formed with an asymmetric shape, as shown in FIG. 29A. More specifically, as shown in FIG. 29A, a vertical centerline 164AC of the wider portion 164A of the via 164 is offset from a vertical centerline 164BC of the narrow portion 164B of the via 164.

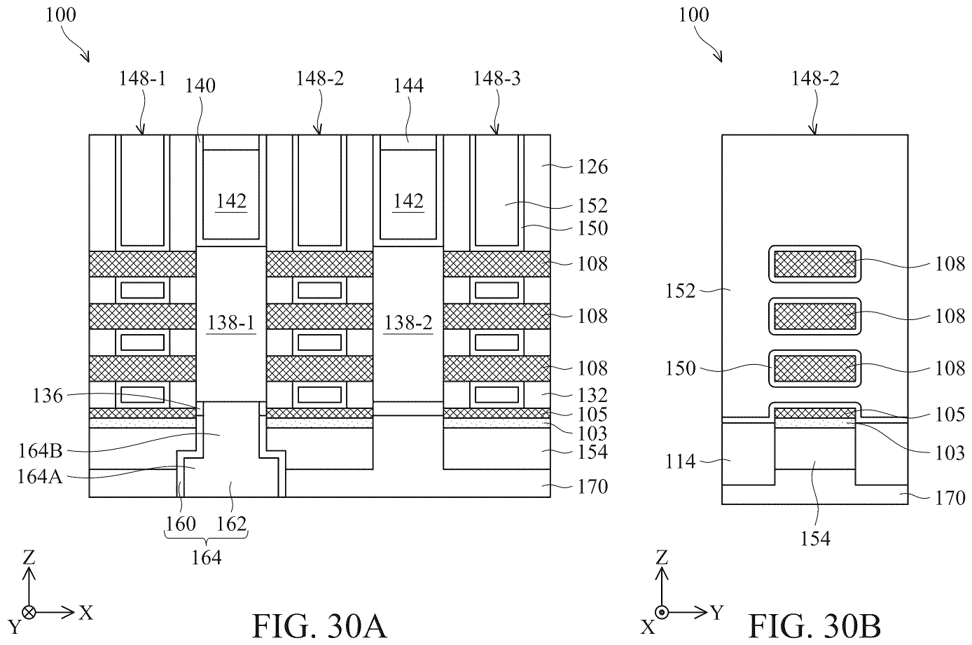

FIGS. 30A and 30B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. The workpiece 100 shown in FIGS. 30A and 30B is similar to the workpiece 100 shown in FIGS. 28A and 28B, except that the liner layer 168 is omitted. As discussed above, the dielectric layer 170 includes a dielectric material, such as Si₃N₄, SiO₂, SiC, SiOC, SiON, SiCN, SiOCN, carbon doped oxide, nitrogen doped oxide, porous oxide, or combinations thereof. If the dielectric layer 170 has oxygen composition (e.g., SiO₂, SiOC, SiON, SiOCN, etc.), the liner layer 168 (shown in FIG. 28A) is used to prevent the oxygen composition in the dielectric layer 170 diffuse into the source/drain feature 138-2.

As shown in FIG. 30A, if the dielectric layer 170 includes Si₃N₄, SiC, SiCN, etc. without oxygen composition, the liner layer 168 can be omitted. In some embodiments, the dielectric layer 170 is separated from the source/drain feature 138-2 by the bottom dielectric layer 136. Furthermore, the dielectric layer 170 is in contact with the via 164 (specifically, the liner layer 160). In some embodiments, the dielectric layer 170, the dielectric layer 154, and the liner layer 160 of the via 164 includes silicon nitride (Si₃N₄).

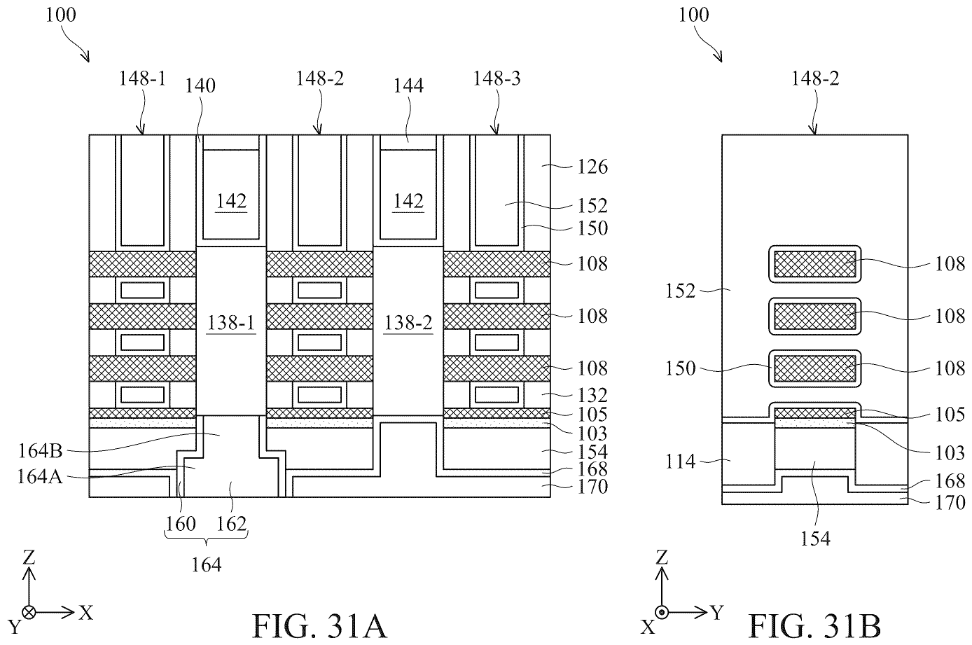

FIGS. 31A and 31B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. The workpiece 100 shown in FIGS. 31A and 31B is similar to the workpiece 100 shown in FIGS. 28A and 28B, except that the bottom dielectric layer 136 are omitted. In the cases that the source/drain features 138 are doped with p-type dopants (i.e., p-type source/drain features), the bottom dielectric layer 136 may be not formed after the formation of the epitaxial layer 134 shown in FIG. 13A and the source/drain features 138 are directly formed over and in contact with the epitaxial layer 134. After the sequent processes discussed above, the liner layer 168 is formed under and in contact with the source/drain feature 138-2, as shown in FIG. 31A. In these cases, the source/drain features 138 (doped with p-type dopants) have a larger volume to keep strain for semiconductor layer 108 for the P-type GAA transistor, thereby improving the performance.

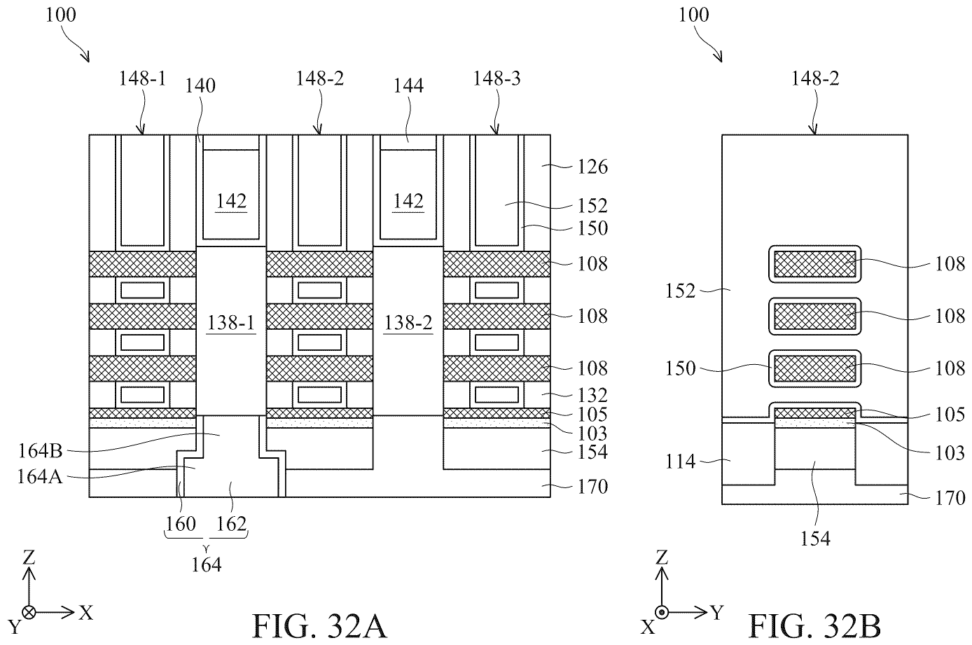

FIGS. 32A and 32B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. The workpiece 100 shown in FIGS. 32A and 32B is similar to the workpiece 100 shown in FIGS. 31A and 31B, except that the liner layer 168 is omitted. Referring back to FIG. 31A, if the dielectric layer 170 has oxygen composition (e.g., SiO₂, SiOC, SiON, SiOCN, etc.), the liner layer 168 is used to prevent the oxygen composition in the dielectric layer 170 diffuse into the source/drain feature 138-2 (doped with p-type dopants).

As shown in FIG. 32A, if the dielectric layer 170 includes Si₃N₄, SiC, SiCN, etc. without oxygen composition, the liner layer 168 can be omitted. In some embodiments, the dielectric layer 170 is separated from the source/drain feature 138-2 by the bottom dielectric layer 136. Furthermore, the dielectric layer 170 is in contact with the via 164 (specifically, the liner layer 160). In some embodiments, the dielectric layer 170, the dielectric layer 154, and the liner layer 160 of the via 164 includes silicon nitride (Si₃N₄).

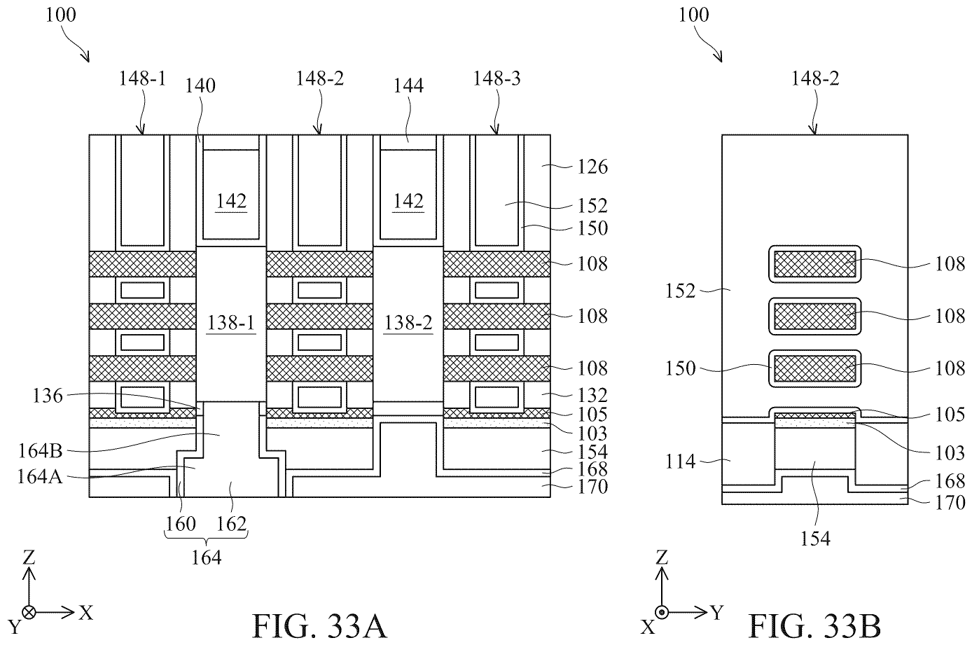

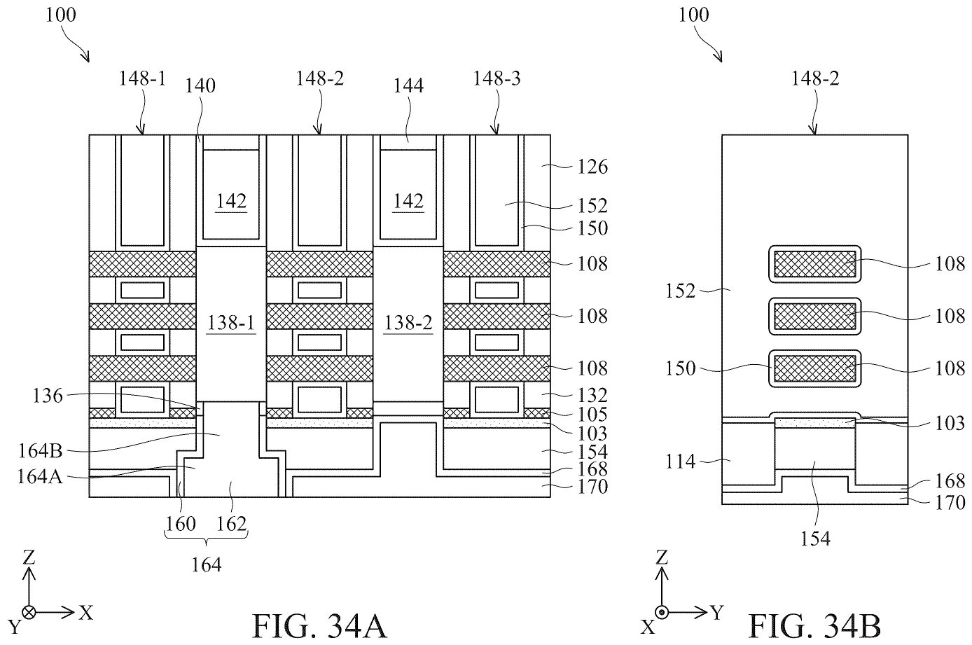

FIGS. 33A and 33B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. FIGS. 34A and 34B are respectively an X-Z cross-sectional view and a Y-Z cross-sectional view of the workpiece 100 at a fabrication stage along the lines A-A′ and B-B′ of FIG. 8, in accordance with some alternative embodiments of the present disclosure. Referring back to FIG. 15A, as discussed above, the semiconductor layer 105 protect the etch stop layer 103 during the removal of the semiconductor layers 106 to prevent damage to the etch stop layer 103. In some embodiments, the semiconductor layer 105 may be partially removed during the removal of the semiconductor layers 106.

Therefore, the semiconductor layer 105 over the etch stop layer 103 may become a non-rectangular shape in the X-Z cross-sectional view. As shown in FIG. 33A, the semiconductor layer 105 is partially removed during the removal of the semiconductor layers 106, such that the etch stop layer 103 has a non-rectangular shape in the X-Z cross-sectional view. In these embodiments, bottom surfaces of the gate structures 148 are lower than a topmost surface of the semiconductor layer 105. As shown in FIG. 34A, portions of the semiconductor layer 105 in direct over the etch stop layer 103 (i.e., exposed in the gate trenches 146) are removed during the removal of the semiconductor layers 106. In these embodiments, the gate structures 148 are over and in contact with the etch stop layer 103, as shown in FIG. 34A.

The embodiments disclosed herein relate to semiconductor structures and their manufacturing methods, and more particularly to methods and semiconductor structures including GAA structures with an etch stop layer under the gate structure, such that the gate structure is protected during the removal of the substrate for the backside interconnection structure. Furthermore, the present embodiments provide one or more of the following advantages. The etch stop layer prevent the fluorination of the gate structure during the removal of the substrate, such that the gate structure will not be damaged, thereby improving the performance of the GAA structures.

Thus, one of the embodiments of the present disclosure describes a method for manufacturing a semiconductor structure that includes forming an etch stop layer over a substrate, and forming a stack over the etch stop layer. The stack includes first semiconductor layers and second semiconductor layers alternating stacked. The method further includes recessing the stack and the etch stop layer to form a fin extending in a first direction, forming a dummy gate structure over the fin and extending in a second direction, forming source/drain trenches on opposite sides of the dummy gate structure in the first direction, forming epitaxial layers in the source/drain trenches, forming source/drain features over the epitaxial layers and in the source/drain trenches, replacing the dummy gate structure and the first semiconductor layers with a gate structure wrapping around the second semiconductor layers, removing the substrate to expose bottom surfaces of the etch stop layer and the epitaxial layers, forming a first dielectric layer under the etch stop layer and the epitaxial layers, and replacing a portion of the first dielectric layer and one of the epitaxial layers with a via under and electrically connected to one of the source/drain features. The second direction is perpendicular to the first direction.

In another of the embodiments, discussed is a method for manufacturing a semiconductor structure including forming a fin over a substrate and extending in a first direction. The fin includes a single crystal layer over the substrate and first semiconductor layers and second semiconductor layers alternating stacked over the single crystal layer. The method further includes forming a dummy gate structure over the fin and extending in a second direction, forming silicon germanium layers on opposite sides of the dummy gate structure in the first direction, forming source/drain features over the silicon germanium layers and on opposite sides of the dummy gate structure in the first direction, replacing the dummy gate structure and the first semiconductor layers with a gate structure wrapping around the second semiconductor layers, replacing the substrate with a first dielectric layer under the single crystal layer and the silicon germanium layers, forming an opening in the first dielectric layer to expose one of the silicon germanium layers, removing the one of the silicon germanium layers, and forming a via in the opening and electrically connected to one of the source/drain features. The second direction is perpendicular to the first direction.

In yet another of the embodiments, discussed is a semiconductor structure including an etch stop layer, semiconductor layers over the etch stop layer and vertically spaced apart from each other, a gate structure wrapping around the semiconductor layers, source/drain features attached to the semiconductor layers, a first dielectric layer under the etch stop layer and the source/drain features, a via passing through the first dielectric layer and electrically connected to one of the source/drain features, and a second dielectric layer under the first dielectric layer, wherein the second dielectric layer is in contact with the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming an etch stop layer over a substrate;
forming a stack over the etch stop layer, wherein the stack comprises first semiconductor layers and second semiconductor layers alternating stacked;
recessing the stack and the etch stop layer to form a fin extending in a first direction;
forming a dummy gate structure over the fin and extending in a second direction, wherein the second direction is perpendicular to the first direction;
forming source/drain trenches on opposite sides of the dummy gate structure in the first direction;
forming epitaxial layers in the source/drain trenches;
forming source/drain features over the epitaxial layers and in the source/drain trenches;
replacing the dummy gate structure and the first semiconductor layers with a gate structure wrapping around the second semiconductor layers;
removing the substrate to expose bottom surfaces of the etch stop layer and the epitaxial layers;
forming a first dielectric layer under the etch stop layer and the epitaxial layers; and
replacing a portion of the first dielectric layer and one of the epitaxial layers with a via under and electrically connected to one of the source/drain features.

2. The method of claim 1, wherein the etch stop layer is single crystal.

3. The method of claim 1, wherein a thickness of the etch stop layer is in a range from about 1 nm to about 3 nm.

4. The method of claim 1, further comprising:
forming a silicon layer over the etch stop layer before the forming of the stack.

5. The method of claim 4, wherein a thickness of the silicon layer is greater than 1 nm.

6. The method of claim 1, further comprising:
forming silicon nitride layers over the epitaxial layers before the forming of the source/drain features.

7. The method of claim 1, wherein the replacing of the portion of the first dielectric layer and the one of the epitaxial layers comprises:
forming an opening in the first dielectric layer to expose one of the silicon germanium layers;
removing the one of the silicon germanium layers to enlarge the opening;
conformally forming a liner layer in the opening;
removing a portion of the liner layer to expose a bottom surface of one of the source/drain features; and
forming the via under and in contact with the one of the source/drain features.

8. The method of claim 1, wherein the enlarged opening has a first portion and a second portion over the first portion, wherein a width of the first portion in the first direction is greater than a width of the second portion in the first direction.

9. The method of claim 1, further comprising:
recessing the first dielectric layer after the replacing of the portion of the first dielectric layer and the one of the epitaxial layers to expose the other one of the epitaxial layers;
removing the other one of the epitaxial layers; and
forming a second dielectric layer under the etch stop layer and the other one of the source/drain features.

10. The method of claim 1, wherein the gate structure is in contact with the etch stop layer in the second direction.

11. A method for manufacturing a semiconductor structure, comprising:
forming a fin over a substrate and extending in a first direction, wherein the fin comprises a single crystal layer over the substrate and first semiconductor layers and second semiconductor layers alternating stacked over the single crystal layer;
forming a dummy gate structure over the fin and extending in a second direction, wherein the second direction is perpendicular to the first direction;
forming silicon germanium layers on opposite sides of the dummy gate structure in the first direction;
forming source/drain features over the silicon germanium layers and on opposite sides of the dummy gate structure in the first direction;
replacing the dummy gate structure and the first semiconductor layers with a gate structure wrapping around the second semiconductor layers;
replacing the substrate with a first dielectric layer under the single crystal layer and the silicon germanium layers;
forming an opening in the first dielectric layer to expose one of the silicon germanium layers;
removing the one of the silicon germanium layers; and
forming a via in the opening and electrically connected to one of the source/drain features.

12. The method of claim 11, wherein a width of the opening in the first direction is greater than a width of the one of the silicon germanium layers in the first direction.

13. The method of claim 11, further comprising:
partially recessing the first dielectric layer after the forming of via;
removing the other one of the silicon germanium layers; and
forming a second dielectric layer under the etch stop layer, the first dielectric layer, and the other one of the source/drain features.

14. The method of claim 13, further comprising:
forming silicon nitride layers over the silicon germanium layers before the forming of the source/drain features,
wherein the second dielectric layer is separated from the other one of the source/drain features by the silicon nitride layers.

15. The method of claim 13, wherein the source/drain features are doped with p-type dopants and the method further comprises:
conformally forming a liner layer in contact with the etch stop layer, the first dielectric layer, and the other one of the source/drain features after the removing the other one of the silicon germanium layers; and
forming the second dielectric layer under the liner layer, wherein the second dielectric layer has an oxygen composition.

16. The method of claim 13, wherein the second dielectric layer is in contact with the other one of the source/drain features.

17. The method of claim 13, wherein the first dielectric layer and the second dielectric layer have the same material.

18. A semiconductor structure, comprising:
an etch stop layer;
semiconductor layers over the etch stop layer and vertically spaced apart from each other;
a gate structure wrapping around the semiconductor layers;
source/drain features attached to the semiconductor layers;
a first dielectric layer under the etch stop layer and the source/drain features;
a via passing through the first dielectric layer and electrically connected to one of the source/drain features; and
a second dielectric layer under the first dielectric layer, wherein the second dielectric layer is in contact with the via.

19. The semiconductor structure of claim 18, wherein the via has a narrow portion and a wider portion under the narrow portion.

20. The semiconductor structure of claim 19, wherein a vertical centerline of the wider portion is offset from a vertical centerline of the narrow portion.
